(19) United States
(12) Patent Application Publication
(10) Pub. No.: US 2022/0198085 A1
(43) Pub. Date: Jun. 23, 2022

(54) METHOD AND SYSTEM FOR DESIGNING BLOCK LAYOUTS FOR USE IN BLOCK PLACEMENT DURING CONSTRUCTION

(71) Applicant: FASTBRICK IP PTY LTD, High Wycombe (AU)

(72) Inventor: Maarten Frank Kornaat, High Wycombe (AU)

(21) Appl. No.: 17/603,803

(22) PCT Filed: Apr. 15, 2020
(86) PCT No.: PCT/AU20/50367

§ 371 Date: Oct. 14, 2021

(30) Foreign Application Priority Data
Apr. 15, 2019 (AU) 2019901296

(51) Int. Cl. G06F 30/13; G06Q 50/08; G06Q 10/06; B25J 9/16; E04B 2/02; E04G 21/18; E04G 21/22

(52) U.S. Cl. CPC G06F 30/13; G06Q 50/08; G06Q 10/0631; E04G 21/22; E04B 2/02; E04G 21/1841; B25J 9/1661

(57) ABSTRACT

A method for designing block layouts for use in block placement during construction, the method including, in one or more electronic processing devices, acquiring plan data indicative of a construction plan, identifying walls and intersections within the construction plan, identifying a number of possible intersection layouts for each intersection, generating different block layouts, each block layout including a combination of intersection layouts, the combination including one of the number of possible intersection layouts for each intersection and at least one wall layout for each wall, the wall layouts being generated based on the combination of intersection layouts and selecting one of the different block layouts.

### BACKGROUND OF THE INVENTION

In one form, the present invention relates to a system and method for designing block layouts for use in block placement during construction. In another form, the present invention relates to a system and method for designing a block sequence for use in ordering blocks for placement during construction. In one particular example, the block layout and/or block sequence is suitable for use in controlling a head of a block laying robot for block placement during construction.

### DESCRIPTION OF THE PRIOR ART

The reference in this specification to any prior publication (or information derived from it), or to any matter which is known, is not, and should not be taken as an acknowledgment or admission or any form of suggestion that the prior publication (or information derived from it) or known matter forms part of the common general knowledge in the field of endeavour to which this specification relates.

It is known to provide systems in which a robot arm mounted on a moving robot base is used to perform interactions within a physical environment. For example, WO 2007/076581 describes an automated brick laying system for constructing a building from a plurality of bricks comprising a robot provided with a brick laying and adhesive applying head, a measuring system, and a controller that provides control data to the robot to lay the bricks at predetermined locations. The measuring system measures in real time the position of the head and produces position data for the controller. The controller produces control data on the basis of a comparison between the position data and a predetermined or pre-programmed position of the head to lay a brick at a predetermined position for the building under construction. The controller can control the robot to construct the building in a course by course manner where the bricks are laid sequentially at their respective predetermined positions and where a complete course of bricks for the entire building is laid prior to laying of the brick for the next course.

WO2018/009985 describes computer aided design software for designing a building or other structure of block construction, where in addition to the usual three dimensional modelling and rendering typical of CAD software, tabular data describing the spatial location and orientation of each block is provided, including information regarding which blocks are cut to length so as to be shortened, and where they are located along each course, and which blocks are machined, drilled or routed for services or other special fittings. Data pertaining to this is compiled in a database for access by control software to control a block laying machine to build a building or other structure from blocks. The database may receive via interface with a scanner, data being a measure of the elevation of the footings and/or concrete pad that has been constructed according to the building plan and for each block of the first course, to determine how much material must be machined off the bottom of each block so that when the first course is laid, the tops of the blocks of the first course are at the same level. This machining data is stored for each block with the tabular data produced by computer aided design software, so that the control software can control the block laying machine to machine and cut each block as per the stored data, and convey each block to the stored position on the footing, pad or previously laid course of blocks, with application of adhesive prior to positioning of the block.

### SUMMARY OF THE PRESENT INVENTION

In one broad form, an aspect of the present invention seeks to provide a method for designing block layouts for use in block placement during construction, the method including, in one or more electronic processing devices: acquiring plan data indicative of a construction plan; identifying walls and intersections within the construction plan; identifying a number of possible intersection layouts for each intersection; generating different block layouts, each block layout including: a combination of intersection layouts, the combination including one of the number of possible intersection layouts for each intersection; and, at least one wall layout for each wall, the wall layouts being generated based on the combination of intersection layouts; and, selecting one of the different block layouts.

In one embodiment, the method includes, in the one or more processing devices, selecting one of the plurality of different block layouts so as to at least one of: minimize a number of blocks used; minimize a number of part blocks used; avoid alignment of blocks in different block courses; and, avoid alignment of block joins in different block courses.

In one embodiment, the method includes, in the one or more processing devices, selecting one of the different block layouts using an optimization algorithm.

In one embodiment, the method includes, in the one or more processing devices: calculating a block layout cost associated with each of a number of different block layouts; and, selecting one of the different block layouts using the block layout costs.

In one embodiment, the method includes, in the one or more processing devices, using an optimization algorithm to minimize the block layout cost.

In one embodiment, the method includes, in the one or more processing devices, calculating the block layout cost using at least one of: a cost associated with a block type; a cost associated with a full block; a cost associated with a part block; a cost associated with an intersection layout; a cost associated with an alignment of blocks in different block courses; and, a cost associated with an alignment of block joins in different block courses.

In one embodiment, the cost associated with each block is less than the cost associated with each part block.

In one embodiment, the method includes, in the one or more processing devices: iteratively generating block layouts using different combinations of intersection block layouts; and, selecting one of the iteratively generated block layouts.

In one embodiment, the method includes, in the one or more processing devices: generating a candidate block layout; iteratively: generating a modified block layout by changing at least one intersection layout in the candidate block layout; comparing the modified block layout and the candidate block layout; and, selectively updating the candidate block layout with the modified block layout depending on results of the comparison; and, when one or more criteria are met, selecting one of the different block layouts by using the candidate block layout.

In one embodiment, the method includes, in the one or more processing devices, generating a candidate block layout by: selecting a candidate intersection layout for each intersection using the possible intersection layouts for each intersection; and, generating a candidate wall layout for each wall in accordance with the candidate intersection layouts.

In one embodiment, the method includes, in the one or more processing devices, generating a modified block layout by: determining a selected intersection in the candidate block layout; and, at least one of: updating a candidate intersection layout of the selected intersection by selecting a next one of the number of possible intersection layouts; and, if each possible intersection layout has been used for the selected intersection, determining a different selected intersection.

In one embodiment, the method includes, in the one or more processing devices, updating the candidate block layout if the modified block layout at least one of: is better than the candidate block layout; and, has a lower cost than the candidate block layout.

In one embodiment, the criteria includes at least one of: a defined total number of iterations have been performed; and, the candidate block layout has not been updated for a defined number of iterations.

In one embodiment, the method includes, in the one or more processing devices, determining possible intersection layouts for an intersection by: determining an intersection type; and, retrieving a list of possible intersection layouts associated with the intersection type.

In one embodiment, the method includes, in the one or more processing devices, determining possible intersection layouts for an intersection by: retrieving layout rules; and, using the layout rules to select possible intersection layouts.

In one embodiment, the layout rules are dependent on a block layout of an adjacent block course.

In one embodiment, each block layout includes at least one of: a single block course of blocks; and, two block courses of blocks.

In one embodiment, the block layouts can include blocks having different block types.

In one embodiment, the different block types include at least one of: blocks for internal walls; blocks for external walls; full blocks; quarter blocks; half blocks; and, three quarter blocks.

In one embodiment, the method includes, in the one or more processing devices, generating a block layout for each of a plurality of block courses.

In one embodiment, the plan data is indicative of wall segments defining at least wall lengths and wall end points.

In one embodiment, the method includes, in the one or more processing devices, acquiring plan data at least one of: using user input commands; from a computer aided design package; and, from a data store.

In one embodiment, a grid is used in designing the block layouts.

In one embodiment, the grid comprises square grid elements.

In one embodiment, dimensions of the grid elements are indicative of a minimum block dimension.

In one embodiment, the minimum block dimension is a block width.

In one embodiment, wall segments are extracted from the plan data and overlayed onto the grid so that each wall segment is indicative of a number of grid elements.

In one embodiment, the different block layouts are generated by fitting different combinations of blocks onto the grid elements associated with each wall segment.

In one embodiment, the method includes, in the one or more processing devices, generating layout data using selected block layout(s).

In one embodiment, the method includes, in the one or more processing devices: acquiring block layout data indicative of block layouts for a number of block courses; identifying one or more sequence rules; generating different block sequences, each block sequence specifying an order in which blocks should be placed and being generated at least in part based on the sequence rules; and, selecting one of the different block sequences.

In one embodiment, the method includes, in the one or more processing devices, generating block sequence data using the selected block sequence.

In one embodiment, there is provided a method for controlling a block laying machine to construct a building, the block laying machine including a block laying head comprising a robot arm and end effector for placing blocks, the block laying head mounted at the end of a boom for positioning the head, the method including in a control system: receiving block layout data generated according to the previously defined method; and, controlling at least one of the boom and robot arm so as to allow the end effector to position blocks according to the block layout data.

In one embodiment, the method includes, in the control system: receiving block sequence data generated according to the previously defined method; and, controlling at least one of the boom and robot arm so as to allow the end effector to position blocks according to the block sequence data.

In one embodiment, the block sequence data results in the block laying machine constructing the building by laying blocks of at least some courses simultaneously.

In another broad form, an aspect of the present invention seeks to provide a system for designing block layouts for use in block placement during construction, the system including, one or more electronic processing devices configured to: acquire plan data indicative of a construction plan; identify walls and intersections within the construction plan; identify a number of possible intersection layouts for each intersection; generate different block layouts, each block layout including: a combination of intersection layouts, the combination including one of the number of possible intersection layouts for each intersection; and, at least one wall layout for each wall, the wall layouts being generated based on the combination of intersection layouts; and, select one of the different block layouts.

In a further broad form, an aspect of the present invention seeks to provide a computer program product for designing block layouts for use in block placement during construction, the computer program product including computer executable code which when executed using one or more suitably programmed electronic processing devices causes the one or more processing devices to: acquire plan data indicative of a construction plan; identify walls and intersections within the construction plan; identify a number of possible intersection layouts for each intersection; generate different block layouts, each block layout including: a combination of intersection layouts, the combination including one of the number of possible intersection layouts for each intersection; and, at least one wall layout for each wall, the wall layouts being generated based on the combination of intersection layouts; and, select one of the different block layouts.

It will be appreciated that the broad forms of the invention and their respective features can be used in conjunction and/or independently, and reference to separate broad forms is not intended to be limiting. Furthermore, it will be appreciated that features of the method can be performed using the system or apparatus and that features of the system or apparatus can be implemented using the method.

### BRIEF DESCRIPTION OF THE DRAWINGS

Various examples and embodiments of the present invention will now be described with reference to the accompanying drawings, in which:

FIG. 1A is a schematic diagram illustrating a first example of a system for placing blocks during construction;

FIG. 1B is a schematic diagram of a second example of a system for placing blocks during construction;

FIG. 1C is a schematic plan view of the system of FIG. 1B;

FIG. 2 is a schematic diagram of an example of a control system for the systems of FIGS. 1A to 1C;

FIG. 3 is a flowchart of an example of a process for placing blocks during construction;

FIG. 4 is a flowchart of an example of a method for designing block layouts for use in block placement during construction;

FIG. 5A is a schematic plan view of a first example of a block layout for a T-shaped intersection;

FIG. 5B is a schematic plan view of a second example of a block layout for a T-shaped intersection;

FIG. 5C is a schematic plan view of a third example of a block layout for a T-shaped intersection;

FIG. 5D is a schematic plan view of a fourth example of a block layout for a T-shaped intersection;

FIG. 5E is a schematic plan view of a fifth example of a block layout for a T-shaped intersection;

FIG. 6A is a schematic plan view of a first example of a block layout for a corner intersection;

FIG. 6B is a schematic plan view of a second example of a block layout for a corner intersection;

FIG. 7A is a schematic plan view of a first example of a block layout for a T-shaped and corner intersection;

FIG. 7B is a schematic plan view of a second example of a block layout for a T-shaped and corner intersection;

FIG. 7C is a schematic plan view of a third example of a block layout for a T-shaped and corner intersection;

FIG. 7D is a schematic plan view of a fourth example of a block layout for a T-shaped and corner intersection;

FIG. 8 is a flowchart of a second example of a method for designing block layouts for use in block placement during construction;

FIGS. 9A to 9D are a flowchart of a specific example of a method for designing block layouts for use in block placement during construction;

FIG. 10 is a flowchart of an example of a method for designing a block sequence for use in placing blocks during construction;

FIG. 11A is a schematic plan view of an example of an end effector of a block laying robot holding a block for placement;

FIG. 11B is a schematic end view of an example of an end effector of a block laying robot holding a block for placement;

FIG. 11C is a schematic side view of an example of an end effector of a block laying robot holding a block for placement;

FIG. 12A is a schematic plan view of an example of a block layout for a corner intersection;

FIG. 12B is a schematic plan view of the block layout of FIG. 12A showing the end effector;

FIG. 13 is a schematic side view of an example of a wall block layout;

FIG. 14A is a schematic plan view of a first example of a block sequence for a building block layout;

FIG. 14B is a schematic plan view of a second example of a block sequence for a building block layout;

FIG. 15 is a flowchart of a second example of a method for designing a block sequence for use in placing blocks during construction;

FIGS. 16A to 16C are a flowchart of a specific example of a method for designing a block sequence for use in placing blocks during construction;

FIGS. 17A and 17B are schematic diagrams of an example of a grid system for use in designing block layouts for use in block placement during construction;

FIG. 18 is a flowchart of a third example of a method for designing a block sequence for use in placing blocks during construction;

FIGS. 19A and 19B are a flowchart of an overview of a specific example of a method for designing a block sequence for use in placing blocks during construction;

FIG. 20 is a flowchart of an example of a method for generating a first block sequence for the method of FIGS. 19A and 19B;

FIGS. 21A and 21B are a flowchart of an example of a method for generating a second block sequence for the method of FIGS. 19A and 19B;

FIGS. 22A and 22B are a flowchart of an example of a method for generating a third block sequence for the method of FIGS. 19A and 19B;

FIGS. 23A and 23B are a flowchart of an example of a method for generating a fourth block sequence for the method of FIGS. 19A and 19B;

FIG. 24A is a schematic diagram of an example of block positions in a block layout;

FIG. 24B is a schematic diagram of an example of a first block sequence for the block layout of FIG. 24A;

FIG. 24C is a schematic diagram of an example of a second block sequence for the block layout of FIG. 24A;

FIG. 24D is a schematic diagram of an example of a third block sequence for the block layout of FIG. 24A; and,

FIG. 24E is a schematic diagram of an example of a final block sequence for the block layout of FIG. 24A.

### DETAILED DESCRIPTION OF THE PREFERRED EMBODIMENTS

The following description explains a number of different systems and methods for performing interactions within an environment, and in one particular example for positioning blocks for use in constructing a building. For the purpose of illustration, the following definitions apply to terminology used throughout.

A “block” is a piece of material, typically in the form of a polyhedron, such as a cuboid having six quadrilateral and more typically substantially rectangular faces. The block is typically made of a hard material and may include openings or recesses, such as cavities or the like. The block is configured to be used in constructing a structure, such as a building or the like and specific example blocks include bricks, besser blocks, or similar. A “course” of blocks is a row of blocks typically provided at a common vertical height.

The term “modular block” is defined as a block having a length divisible by its width resulting in an integer number. For example, a 400 mm×100 mm block is modular as is a 500 mm×125 mm block. It should further be noted that the above dimensions of the block may be an envelope providing for an actual dimension plus a spacing around the block. For example, a 500×125 mm block, may have an “actual” length of 490 mm and an actual “width” of 115 mm with a 5 mm tolerance or spacing around its perimeter being specified as part of its overall dimensions. This may ensure for example, that when positioned, adjacent blocks have a spacing between them.

The term “interaction” is intended to refer to any physical interaction that occurs within, and including with or on, an environment. Example interactions could include placing material or objects within the environment, removing material or objects from the environment, moving material or objects within the environment, modifying, manipulating, or otherwise engaging with material or objects within the environment, modifying, manipulating, or otherwise engaging with the environment, or the like. Further examples of interactions will become apparent from the following description, and it will be appreciated that the techniques could be extended to a wide range of different interactions, and specified examples are not intended to be limiting. Furthermore, in some examples, interactions may comprise one or more distinct steps. For example, when block laying, an interaction could include the steps of retrieving a block from a block supply mechanism and then placing the brick in the environment.

The term “environment” is used to refer to any location, region, area or volume within which, or on which, interactions, such as block laying, are performed. The type and nature of the environment will vary depending on the preferred implementation and the environment could be a discrete physical environment, and/or could be a logical physical environment, delineated from surroundings solely by virtue of this being a volume within which interactions occur. Non-limiting examples of environments include building or construction sites, and in particular, building slabs, parts of vehicles, such as decks of ships or loading trays of lorries, factories, loading sites, ground work areas, or the like, and further examples will be described in more detail below.

A robot arm is a programmable mechanical manipulator. In this specification a robot arm includes multi axis jointed arms, parallel kinematic robots (such as Stewart Platform, Delta robots), spherical geometry robots, Cartesian robots (orthogonal axis robots with linear motion) etc.

A boom is an elongate support structure such as a slewing boom, with or without stick or dipper, with or without telescopic elements, telescoping booms, telescoping articulated booms. Examples include crane booms, earthmover booms, truck crane booms, all with or without cable supported or cable braced elements. A boom may also include an overhead gantry structure, or cantilevered gantry, or a controlled tensile truss (the boom may not be a boom but a multi cable supported parallel kinematics crane (see PAR systems, Tensile Truss—Chernobyl Crane)), or other moveable arm that may translate position in space.

An end effector is a device at the end of a robotic arm designed to interact with the environment. An end effector may include a gripper, nozzle, sand blaster, spray gun, wrench, magnet, welding torch, cutting torch, saw, milling cutter, router cutter, hydraulic shears, laser, riveting tool, or the like, and reference to these examples is not intended to be limiting. For the purposes of a block laying robot for use in automated building construction, the end effector is typically a gripper which may have clamps or jaws to grip a block or other suitable means of attachment including for instance suction pads.

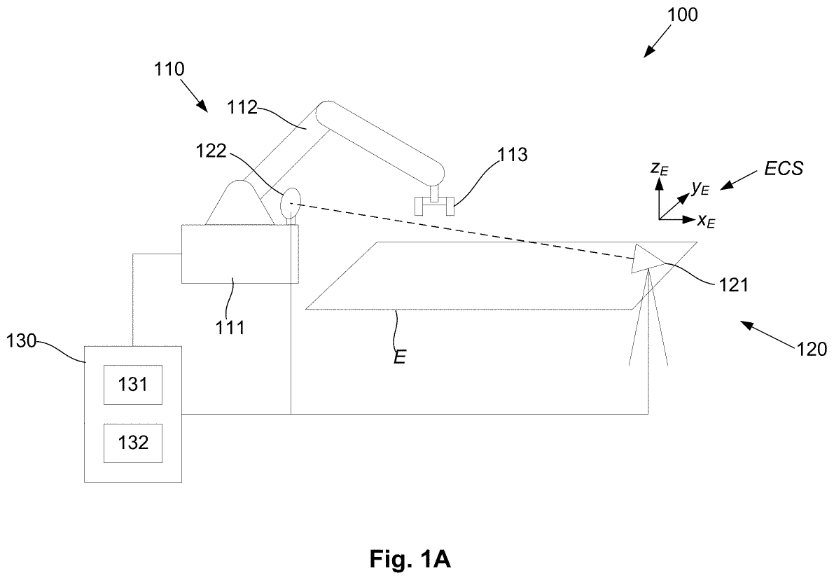

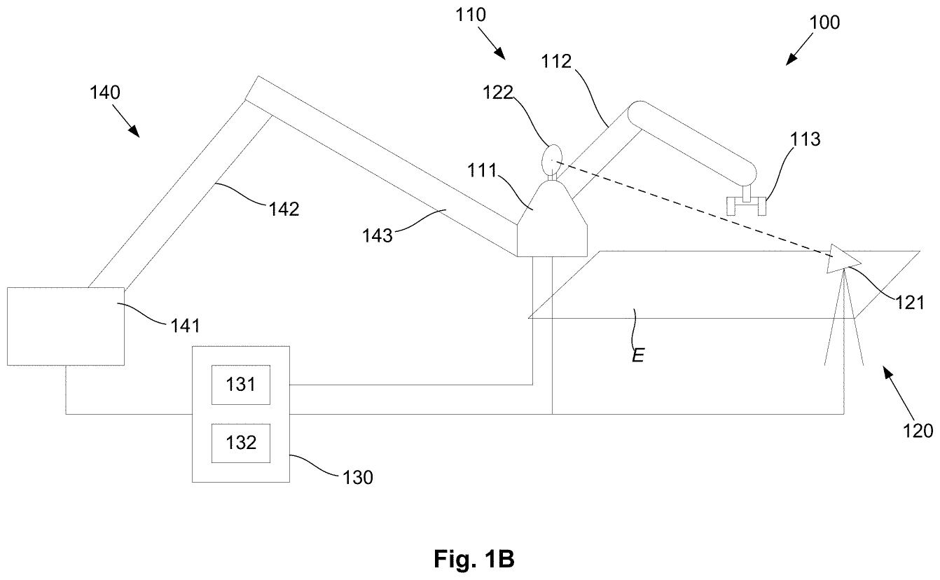

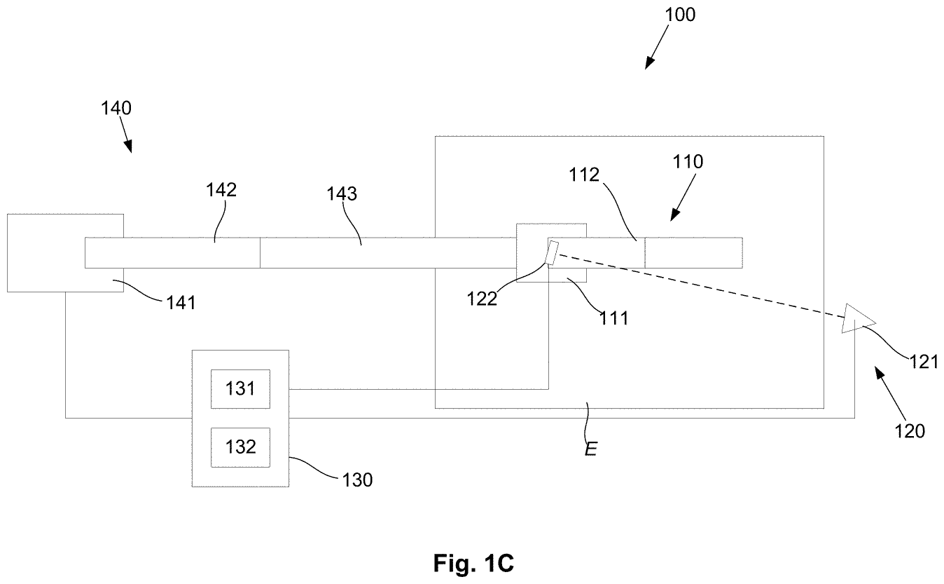

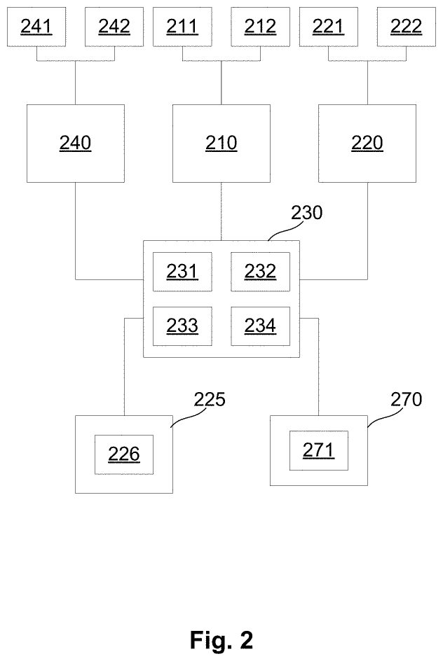

Examples of systems for performing interactions within physical environments, and in particular, positioning blocks on a slab or other similar arrangement for the purpose of constructing a building, will now be described with reference to FIGS. 1A to 1C and FIG. 2.

In the example of FIG. 1A, the system 100 includes a robot assembly 110 including a head, which in this example, includes a robot base 111, a robot arm 112 and an end effector 113. The robot assembly 110 is positioned relative to an environment E, which in this example is illustrated as a 2D plane, such as a construction slab, but in practice could be a 3D volume of any configuration, for example encompassing positioning blocks on top of a course of blocks, which is in turn positioned on a slab. In use, the end effector 113 is used to perform interactions within the environment E, for example to perform block laying, object manipulation, or the like.

The system 100 also includes a tracking system 120, which is able to track the robot assembly movement, and in one particular example, movement of the robot base 111 relative to the environment. In one example, the tracking system includes a tracker base 121, which is typically statically positioned relative to, and typically offset from the environment E, and a tracker target 122, mounted on the robot base 111, allowing a position of the robot base 111 relative to the environment E to be determined.

In one example, the tracking system 120 includes a tracking base 121 including a tracker head having a radiation source arranged to send a radiation beam to the target 122 and a base sensor that senses reflected radiation. A base tracking system is provided which tracks a position of the target 122 and controls an orientation of the tracker head to follow the target 122. In one example, the target 122 includes a target sensor that senses the radiation beam and a target tracking system that tracks a position of the tracking base and controls an orientation of the target to follow the tracker head. In other examples, the target 122 is a passive instrument that does follow the tracker head. Angle sensors are provided in the tracker head that determine an orientation of the head (e.g. in elevation and azimuth). Optionally, angle sensors are also provided in the target that determine an orientation of the target. A processing system determines a position of the target relative to the tracker base in accordance with signals from the sensors, specifically using signals from the angle sensors to determine relative angles between the tracker and target, whilst time of flight of the radiation beam can be used to determine a physical separation, thereby allowing a position of the target relative to the tracking base to be determined. In a further example, the radiation can be polarised in order to allow a roll angle of the target relative to the tracking base to be determined.

Although a single tracking system 120 including a tracker head and target is shown, this is not essential and in other examples multiple tracking systems and/or targets can be provided as will be described in more detail below. In some examples, the tracking system may include tracker heads positioned on the robot base configured to track one or more targets located in the environment.

In one particular example, the tracking system is a laser tracking system and example arrangements are manufactured by API (Radian and OT2 optionally with STS (Smart Track Sensor)), Leica (AT960 and Tmac) and Faro. These systems measure position at 300 Hz, or 1kHz or 2 kHz (depending on the equipment) and rely on a combination of sensing arrangements, including laser tracking, vision systems using 2D cameras, accelerometer data such as from a tilt sensor or INS (Inertial navigation System) and can be used to make accurate measurements of position, with data obtained from the laser tracker and optionally the target equating to position and optionally orientation of the target relative to the environment E. The target may be any suitable optical target including for instance a spherically mounted retroreflector (SMR) or the like. As such systems are known and are commercially available, these will not be described in any further detail.

It will also be appreciated that other position/movement sensors, such as an inertial measurement unit (IMU) can also be incorporated into the system.

In practice, in the above described examples, the robot base 111 undergoes movement relative to the environment E. The nature of the movement will vary depending upon the preferred implementation. For example, the robot base 111 could be mounted on tracks, wheels or similar, allowing this to be moved within the environment E.

Alternatively, in the example shown in FIG. 1B, the robot base 111 is supported by a robot base actuator 140, which can be used to move the robot base. In this example, the robot base actuator is in the form of a boom assembly including a boom base 141, boom 142 and stick 143. The boom is typically controllable allowing a position and/or orientation of the robot base to be adjusted. The types of movement available will vary depending on the preferred implementation. For example, the boom base 141 could be mounted on a vehicle allowing this to be positioned and optionally rotated to a desired position and orientation. The boom and stick 142, 143 can be telescopic arrangements, including a number of telescoping boom or stick members, allowing a length of the boom or stick to be adjusted. Additionally, angles between the boom base 141 and boom 142, and boom 142 and stick 143, can be controlled, for example using hydraulic actuators, allowing the robot base 111 to be provided in a desired position relative to the environment E.

An example of a system of this form for laying blocks, such as bricks, is described in WO2018/009981 the content of which is incorporated herein by cross reference. It will be appreciated however that such arrangements are not limited to block laying, but could also be utilised for other forms of interactions.

In the systems shown in FIGS. 1A and 1B, a control system 130 is provided in communication with the tracking system 120 and the robot assembly 110 allowing the robot assembly to be controlled based on signals received from the tracking system. The control system typically includes one or more control processors 131 and one or more memories 132. For ease of illustration, the remaining description will make reference to a processing device and a memory, but it will be appreciated that multiple processing devices and/or memories could be used, with reference to the singular encompassing the plural arrangements and vice versa. In use the memory stores control instructions, typically in the form of applications software, or firmware, which is executed by the processor 131 allowing signals from the tracking system 120 and robot assembly 110 to be interpreted and used to control the robot assembly 110 to allow interactions to be performed.

An example of the control system 130 is shown in more detail in FIG. 2.

In this example the control system 230 is coupled to a robot arm controller 210, a tracking system controller 220 and a boom controller 240. This is typically performed via a suitable communications network, including wired or wireless networks, and more typically an Ethernet or Ethercat network. The robot arm controller 210 is coupled to a robot arm actuator 211 and end effector actuator 212, which are able to control positioning of the robot arm 112 and end effector 113, respectively. The tracking system controller 220 is coupled to the tracking head 221 and target 222, allowing the tracking system to be controlled and relative positions of the tracking head 221 and target 222 to be ascertained and returned to the control system 230. The boom controller 240 is typically coupled to boom actuators 241, 242 which can be used to position the boom and hence robot base. A second tracking system 225 may also be provided, which includes sensors 226, such as inertial sensors, optionally coupled to a controller or processor. It is to be understood that in practice the robot arm, end effector and boom will have multiple actuators such as servo motors, hydraulic cylinders and the like to effect movement of their respective axes (i.e. joints) and reference to single actuators is not intended to be limiting.

In this example, the control system 230 is also coupled to an optional sensing system 270, including one or more sensors 271, which could be configured to sense additional markers, or other aspects of machine operation.

Each of the robot arm controller 210, tracking system controller 220, second tracking system 225, boom controller 240 and sensing system 270 typically include electronic processing devices, operating in conjunction with stored instructions, and which operate to interpret commands provided by the control system 230 and generate control signals for the respective actuators and/or the tracking system and/or receive signals from sensors and provide relevant data to the control system 230. The electronic processing devices could include any electronic processing device such as a microprocessor, microchip processor, logic gate configuration, firmware optionally associated with implementing logic such as an FPGA (Field Programmable Gate Array), or any other electronic device, system or arrangement. It will be appreciated that the robot arm controller 210, tracking system controller 220 and boom controller 240 typically form part of the boom assembly, robot assembly and tracking system, respectively. As the operation of such systems would be understood in the art, these will not be described in further detail.

The control system 230 typically includes an electronic processing device 231, a memory 232, input/output device 233 and interface 234, which can be utilised to connect the control system 230 to the robot arm controller 210, tracking system controller 220 and boom controller 240. Although a single external interface is shown, this is for the purpose of example only, and in practice multiple interfaces using various methods (e.g. Ethernet, serial, USB, wireless or the like) may be provided.

In use, the processing device 231 executes instructions in the form of applications software stored in the memory 232 to allow the required processes to be performed. The applications software may include one or more software modules, and may be executed in a suitable execution environment, such as an operating system environment, or the like.

Accordingly, it will be appreciated that the control system 230 may be formed from any suitable processing system, such as a suitably programmed PC, computer server, or the like. In one particular example, the control system 230 is a standard processing system such as an Intel Architecture based processing system, which executes software applications stored on non-volatile (e.g., hard disk) storage, although this is not essential. However, it will also be understood that the processing system could be any electronic processing device such as a microprocessor, microchip processor, logic gate configuration, firmware optionally associated with implementing logic such as an FPGA (Field Programmable Gate Array), or any other electronic device, system or arrangement.

It will also be appreciated that the above described arrangements are for the purpose of illustration only and practice a wide range of different systems and associated control configurations could be utilised. For example, it will be appreciated that the distribution of processing between the controllers and/or control system could vary depending on the preferred implementation.

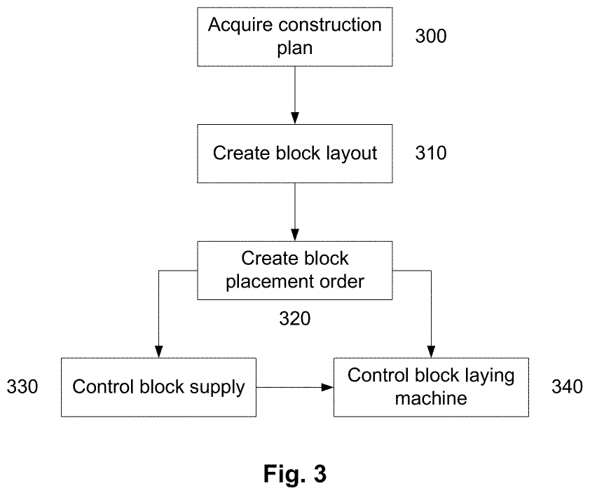

An overview of an example process for placing blocks in an environment E will now be described with reference to FIG. 3.

For the purpose of illustration, it is assumed that the process is performed at least in part using one or more electronic processing devices forming part of one or more processing systems, such as computer systems, servers, or the like, which are optionally connected to other processing systems and one or more client devices, such as mobile phones, portable computers, tablets, or the like, via a network architecture, as will be described in more detail below. For ease of illustration the remaining description will refer to a processing device, but it will be appreciated that multiple processing devices could be used, with processing distributed between the devices as needed, and that reference to the singular encompasses the plural arrangement and vice versa.

In one particular example, the processing device is part of a processing system such as an Intel Architecture based processing system, which executes software applications stored on non-volatile (e.g., hard disk) storage, although this is not essential. However, it will also be understood that the processing system could be any electronic processing device such as a microprocessor, microchip processor, logic gate configuration, firmware optionally associated with implementing logic such as an FPGA (Field Programmable Gate Array), or any other electronic device, system or arrangement.

For the purpose of illustration, it will be assumed that the blocks are placed using a block laying machine or robot similar to that described above with respect to FIGS. 1A to 1C, and FIG. 2, although it will be appreciated that this is not intended to be limiting, and does not preclude the process being implemented with other block laying arrangements, including but not limited to other designs of brick or block laying machines, or manual brick or block laying techniques. In this regard, it will be appreciated that the techniques described herein are designed to optimise the layout and placement of blocks, so as to minimise block usage and wastage, and also reduce a travel path to place the blocks, and hence could be used in manual processes.

Whilst the processing device could form part of the control system 230, more typically the processing device is remote to the control system, with block layout data and/or block sequence data being provided to the control system 230 to allow the block laying machine to be controlled as will be apparent from the description below.

In this example, at step 300 the processing device acquires a construction plan, such as a building plan, or similar. The construction plan could be acquired in any suitable manner, and may be determined in accordance with user input commands, provided via a user interface or similar, which define the construction plan. Alternatively, the construction plan could be received from software, such as a Computer Aided Design (CAD) software application, which is used to construct the plan, such as an architectural software package (e.g. Revit, ArchiCAD), or more general CAD package such as SolidWorks, or the like. In a further example, the construction plan could be retrieved from a database or other repository. The construction plan typically specifies details of any walls to be constructed, including a start and end point of the walls, and any other relevant information, such as the types of blocks to be used, a wall width, wall height, or similar as well as position of windows, doors etc.

At step 310, the processing device creates a block layout. The block layout specifies the location in which each block should be placed in order to build the construction. In one example, the block layout is created in order to minimise the number of blocks used, whilst also taking into account other requirements, such as the need to avoid joins between blocks aligning over multiple courses. The block layout is typically created by considering multiple different layouts, and in one example, by using an iterative optimisation process. The block layout is typically specified in terms of a position coordinate (X, Y, Z) and rotation for each block, although it will be appreciated that other suitable arrangements could be used.

At step 320, the processing device uses the block layout to create a block sequence (i.e. block placement order). The block sequence specifies the order in which each block should be placed in order to construct the building plan, and in particular the block layout. Thus, assuming a block laying machine is used, the block layout and block sequence collectively define a path that the head of the block laying machine, and in particular the robot base 111 and end effector 113, should traverse in order to place the blocks. In one example, the block sequence is created in order to minimise the distance traversed, whilst also taking into account other requirements, such as dependencies, which represent the need to place particular combinations of blocks in a particular order, for example to avoid overhangs during construction, end effector gripper clashes with previously laid blocks or similar. The block sequence is typically created by considering multiple different block sequences, and in one example, by using an iterative optimisation process. The block sequence is typically specified in terms of an ordered list of blocks, with the position of each block being defined in the block layout, although it will be appreciated that other suitable arrangements could be used.

At step 330, the block layout and/or block sequence can be used to control a block supply, for example to ensure the correct amount of blocks are delivered to site to allow construction to be performed. The blocks can be provided in different types, with the required number of each type being supplied. Optionally, the blocks can be supplied in accordance with the sequence, so that blocks are removed from a pallet or other supply in turn, and then placed directly in accordance with the block sequence. This is not essential however, and alternatively the blocks could be provided and ordered as needed.

At step 340, the blocks can be placed, for example by controlling a block laying machine similar to that previously described, thereby allowing the building to be constructed. In this example, the block layout and block sequence can be uploaded to the control system 230 as block layout data and block sequence data respectively. The control system is then able to control the block laying machine in accordance with the block layout and block sequence, for example controlling the boom to position the robot base 111, and controlling the robot arm 112 to position the end effector 113, so that the blocks are placed at the correct location in the correct order, thereby allowing a building or other structure to be constructed.

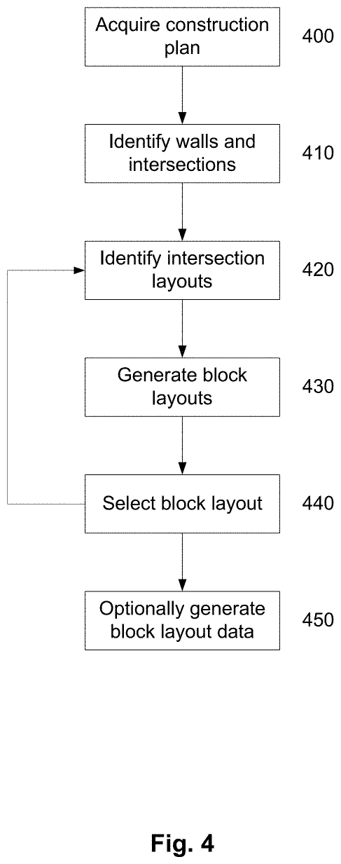

An example of a method for designing block layouts for use in block placement during construction will now be described with reference to FIG. 4.

In this example, at step 400, the processing device acquires plan data indicative of a construction plan, such as building plans, or similar. As previously mentioned, this can be achieved in a variety of manners, including allowing a user to define the construction plan, receiving the construction plan from CAD software, retrieving the construction plan from a database, or the like.

At step 410, the processing device analyses the construction plan to identify walls and intersections within the construction plan. In this regard, the construction plan will typically specify the locations of wall end points, with the processing system using these to identify the location and dimensions of each wall, as well as the location and nature of any intersections between walls, such as corner, T-junction, cross road intersections, or similar.

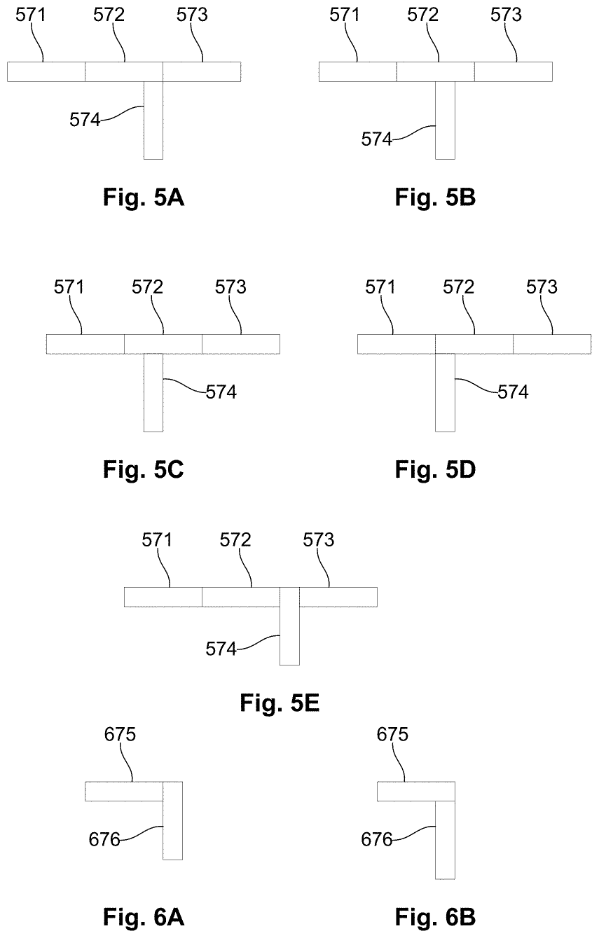

At step 420, the processing device identifies a number of possible intersection layouts for each intersection. In general, each type of intersection will have a number of different possible block layouts for the intersection, and schematic examples of these are shown in FIGS. 5A to 5E and 6A and 6B.

For example, for a T-shaped intersection, including three blocks 571, 572, 573 forming part of a wall, and a perpendicular block 574, five different configurations using full blocks are shown. Specifically, in this example, the blocks are four times longer than the block width, meaning the perpendicular block 574 can be provided in abutment with the side of one of the blocks 572 at each of four locations. Alternatively, the perpendicular block 574 can be provided between the blocks 572, 573 as shown in FIG. 5E. In contrast, for a corner intersection, only two arrangements are feasible using full blocks, including having a first block 675 abut an edge of a perpendicular block 676, or vice versa.

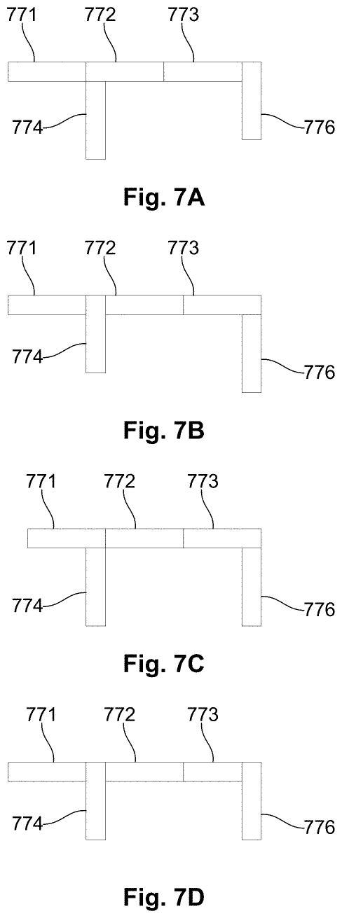

It will similarly be appreciated that intersections could be combined in a variety of ways, and some examples are shown in FIGS. 7A to 7D, in which blocks 771, 772, 773, are combined with two perpendicular blocks 774, 776 extending outwardly therefrom to form a wall with spaced perpendicular blocks 774, 776.

It will be appreciated that the above described arrangements are limited to using identical full blocks, but that other blocks could be used, such as different types of block or part blocks, such as quarter, half or three quarter blocks, resulting in a greater number of intersection layouts. For example, in the arrangement of FIG. 7D, a partial block 773 is used to maintain a spacing between the blocks 774, 776.

The different intersection layouts for each style of intersection are typically previously defined and stored in a database or other repository, allowing these to be retrieved for each intersection in the construction plan, once a type of each intersection is known. However, this is not essential, and alternatively, intersection block layouts can be generated on demand as needed.

In this case, when generating an intersection on demand, the approach could include a brute force methodology, simply calculating every possible layout for the intersection to work. However, for a complex intersection the number of variations can quickly exceed a hundred thousand. As an alternative approach, the processing device can examine a more limited number of blocks, such as two blocks at a time, and check what combination would cause it to clash, then removing these combinations from a list of available combinations. This approach significantly reduces the number of computations required to achieve a suitable intersection layout when using a brute force approach to populate blocks at an intersection.

At step 430, the processing device uses the intersection layouts in order to generate different block layouts. In this regard, each block layout typically includes a combination of intersection layouts, including one of the number of possible intersection layouts for each intersection and at least one wall layout for each wall.

Thus, the processing device can select a possible intersection layout for each intersection, and then simply fill in blocks between the intersection layouts to thereby create the wall layouts. In this regard, the wall layouts will typically be constructed by backfilling full blocks, only using partial blocks as needed to ensure the walls completely join the intersection layouts. This process may take into account certain rules, such as ensuring joins between blocks (e.g. perp joins) do not align with joins on a previous course.

This process is repeated so a number of different block layouts are created, with one of these being selected for use at step 440, for example, based on the number of blocks used in the layout. At step 450, the processing device optionally generates block layout data which may include for example a block identifier, position and orientation data for each block in the layout as well as dependency information associated with a particular block.

Thus, the above described process operates by generating multiple different block layouts based on intersection block layouts, which are then connected to define a block layout for one or more courses of blocks within the building. By generating multiple block layouts, this allows a block layout to be selected which is most appropriate, and for example satisfies certain criteria, such as minimising an overall number of blocks used or number of part blocks used, which in turn minimises the costs and time for the construction to be completed.

A number of further features will now be described.

In one example, the processing device selects one of the plurality of different block layouts so as to minimize a number of blocks used, minimize a number of part blocks used, avoid alignment of blocks in different block courses, avoid alignment of block joins in different block courses, or the like. It will be appreciated that the particular rules utilized will vary depending on the preferred implementation. For example, in some projects aesthetic conditions might be given a higher priority over the number of blocks used, whereas in other projects minimizing the number of blocks might be the sole criteria. Meanwhile avoiding alignment of joins between courses can assist in ensuring the structural strength of the resulting structure.

In one preferred example, the processing device selects one of the different block layouts using an optimization algorithm, and in particular an iterative optimization algorithm. In this regard, the total number of possible layouts is large, and will typically increase exponentially as the construction plan increases in size. Consequently, it is not generally feasible to calculate and consider all possible block layouts for a building. Instead an iterative optimisation algorithm can be used to obtain a solution that is close to optimal, such as a Monte Carlo or Las Vegas algorithms, simulated annealing, or the like. From this it will be appreciated that a wide variety of heuristic approaches to optimization can be used.

In one example, the processing device calculates a block layout cost associated with each of a number of different block layouts and then selects one of the different block layouts using the block layout costs. The cost can be calculated by associating a cost with different considerations, such as by having a cost associated with each block type, each block, each part block, each intersection layout, an alignment of blocks in different block courses or an alignment of block joins in different block courses. In this instance assigning different costs to each of the considerations, allows the relative priority of each of these factors to be easily adjusted, depending on the requirements of the current project. For example, by setting the cost associated with each block to be less than the cost associated with each part block, this will prioritise the inclusion of full blocks in the block layout, avoiding the use of part blocks where possible.

The processing system can then calculate an overall cost for each block layout and select the layout with the lowest cost. In one example, this involves using an optimization algorithm to minimise the block layout cost, with this process optionally being performed using the cost as a measure of fitness, so that block layouts are iteratively modified so as to improve the fitness and lower the cost, with worse block layouts being discarded, and better block layouts being used as a basis for further modified layouts.

In one example, the processing device iteratively generates block layouts using different combinations of intersection block layouts and then selects one of the iteratively generated block layouts. In particular, the processing device generates a candidate block layout, and then generates a modified block layout by changing at least one intersection layout in the candidate block layout. The processing device then compares the modified block layout and the candidate block layout and selectively updates the candidate block layout with the modified block layout depending on results of the comparison. This generally occurs if the modified block layout is better than the candidate block layout, and in particular has a lower cost than the candidate block layout.

This process can be repeated iteratively so as to progressively improve the candidate block layout. Thus, in this example, any worse modified layouts are discarded, with the processing device trying multiple different layouts over multiple different iterations. This typically continues until one or more criteria are met, such as a defined total number of iterations have been performed or the candidate block layout has not been updated for a defined number of iterations, at which point the candidate block layout is used as the block layout.

The number of iterations performed will vary depending on the preferred implementation and can range from a single iteration, through to many iterations, depending on the level of refinement required. For example, if designs are planned months in advance, the algorithm can be configured to find an optimal solution, whereas if the design is required in a short time frame, then an optimal design might be sacrificed for speed. This latter case might arise if a designer, such as an architect wishes to generate an example layout to ensure a design is technically feasible to build, with a more refined layout being generated once the design is finalised. In this instance, a single or small number of iterations could be performed as a feasibility check, with more iterations being used to generate final plans for construction.

Each candidate block layout is typically generated by selecting a candidate intersection layout for each intersection using the possible intersection layouts for each intersection and generating a candidate wall layout for each wall in accordance with the candidate intersection layouts. In particular, the processing device can select an intersection in the candidate block layout and then either update a candidate intersection layout of the selected intersection by selecting a next one of the number of possible intersection layouts, or if each possible intersection layout has been used for the selected intersection, determining a different selected intersection.

Selection of an intersection layout can be achieved by determining an intersection type, retrieving a list of possible intersection layouts associated with the intersection type, and then selecting a next intersection. Additionally and/or alternatively, this can be achieved by retrieving layout rules and then using layout rules to select possible intersection layouts. In one example, the layout rules used are determined in accordance with a block layout of an adjacent block course, thereby, for example, preventing intersection layouts being identical on adjacent courses. In either case, the algorithm can progressively work through the different possible intersection block layouts until the criteria are met.

In the above approach, each intersection block layout is tried in turn until the criteria are met. However, this is not essential and other adaptive algorithms could be used. For example if an intersection layout for a particular intersection results in a significantly reduced cost, this could be fixed for subsequent iterations, with layouts of other intersections being altered to try further variations. Alternatively, the cost could be used as a fitness score to guide the modification process, with modifications being performed to high scoring (low cost) layouts as opposed to other layouts.

In one example, the layout rules selected are dependent on a block layout of an adjacent block course, thereby ensuring the courses are compatible, for example to prevent joins in adjacent courses aligning, which could adversely affect the structural integrity of the wall.

As previously mentioned, the above process can be performed using blocks having different block types, such as blocks for internal walls, blocks for external walls, full blocks, or part blocks such as quarter blocks, half blocks or three quarter blocks, and more typically combinations thereof. In practice, any suitable modular block can be used and as such part blocks may be indicative of third blocks, two third blocks, or fifth blocks, two fifth, three fifth, four fifth blocks etc. depending on the geometry. Typically, the blocks have a number of cavities running through them such that each part block retains at least one cavity.

Each block layout could define a single course of blocks, although this is not essential and alternatively the block layout could define two or more courses of blocks. This has the benefit that the iteration process is performed over multiple courses, avoiding for example, an upper course being constrained to an undesirable configuration by virtue of the block layout for a preceding course having already been set. It will be appreciated however that the larger the number of courses involved, the more computational complex the design process becomes, and so the number of courses might be defined based on available computational requirements and time.

Once generated, the processing system can generate layout data including block layouts, for one or more courses, with the block layout data optionally being used in a sequencing process, as will be described in more detail below.

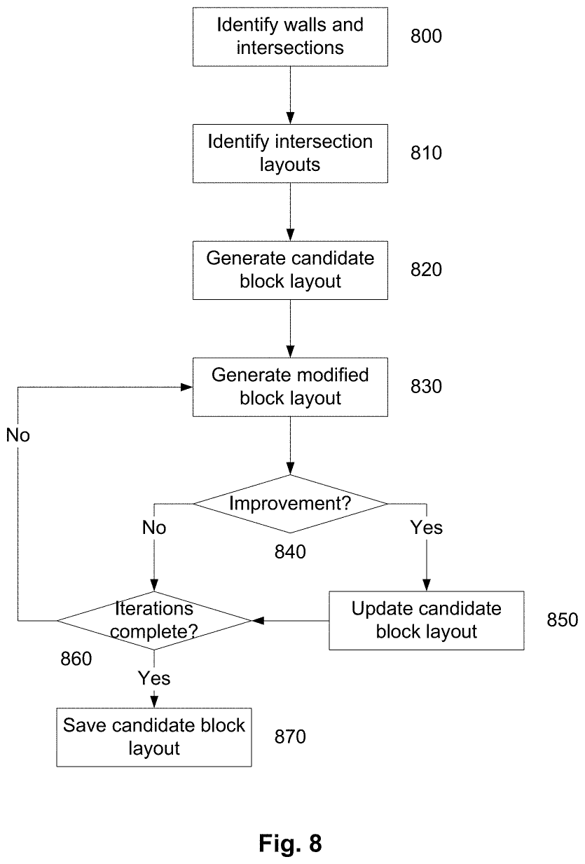

A further example of a method for designing block layouts for use in block placement during construction will now be described with reference to FIG. 8.

In this example, at step 800, having received the construction plan, the processing device identifies walls and intersections, typically by identifying wall end points and using these to resolve the wall and intersection locations. At step 810, the processing device determines a list of possible intersection layouts for each intersection, either by generating these or retrieving a list of intersection layouts based on an intersection type of each intersection.

A candidate block layout is generated at step 820, typically by selecting a first possible intersection layout for each intersection, and then calculating wall block layouts joining the intersection block layouts.

At step 830 a modified block layout is created by altering one of the intersection block layouts, with the modified and candidate block layouts being compared to determine if there is any improvement at step 840. This will typically involve calculating a cost for each block layout, based on the cost of individual components such as each block, and then comparing the costs, with the lower cost representing the better of the candidate and modified block layouts.

If the modified block layout represents an improvement, then the current candidate block layout is replaced with the modified block layout at step 850, otherwise the current candidate block layout is retained.

At step 860 it is determined if the iterations are complete, for example if a required number of iterations have been completed, or the current candidate block layout is deemed acceptable, and if not, the process returns to step 830 to generate a new modified block layout. Otherwise, the candidate block layout is saved for later use.

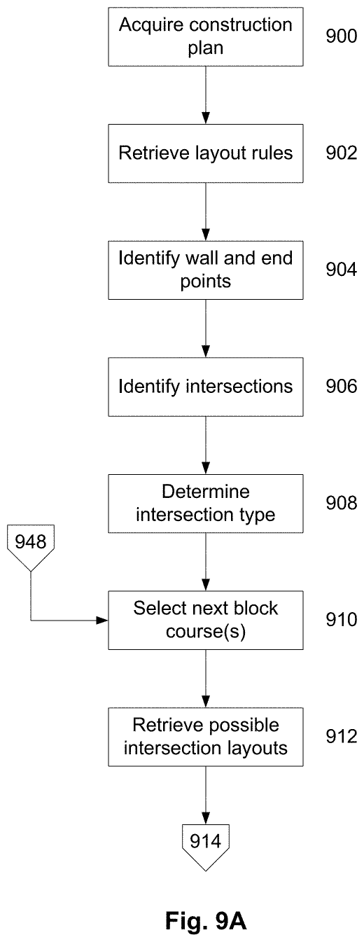

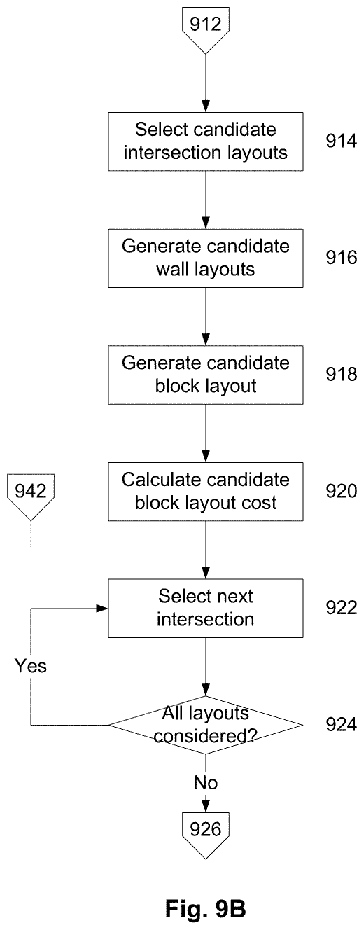

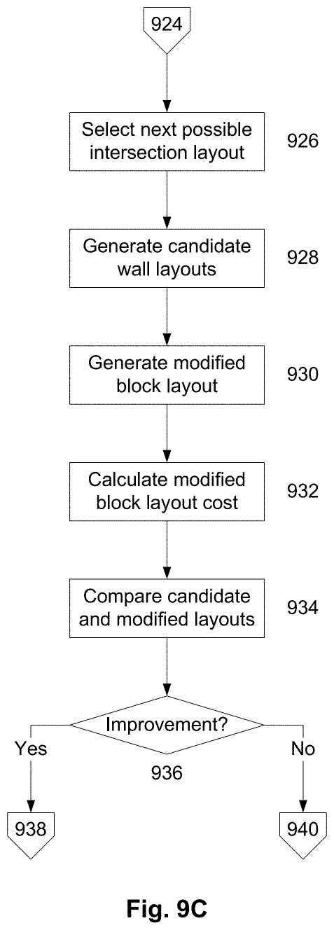

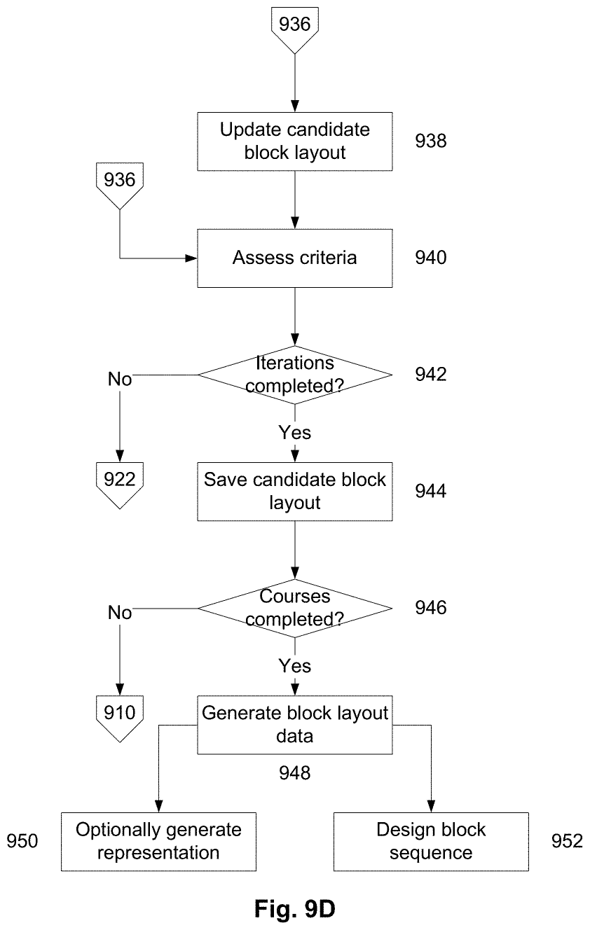

A further specific example of a method for designing block layouts for use in block placement during construction will now be described with reference to FIGS. 9A to 9D.

In this example, the processing device acquires a construction plan at step 900. The manner in which this is performed will vary depending on how the construction plan is defined, but in one example, the construction plan is generated as CAD data by a CAD package. Separate software can be provided for performing the block layout design process, in which case the CAD data might need to be exported. However, this is not essential and in one example, the CAD package software can include a plug-in, which performs the block layout design process. For example, this could be provided as a DLL (Dynamic Linked Library) with exposed code methods which can be implemented within the CAD software.

At step 902, the processing device retrieves layout rules, which can be used to control the block layout design. The layout rules can define limitations on how the block layout should be created, and a wide range of limitations could be defined. For example, the layout rules could place restrictions on how blocks on different courses align, the types of blocks that can be used, limits on the number of partial blocks in any one wall, or course, or the like. Layout rules might also specify how blocks are to be provided near features, such as electrical or plumbing cuts, roof stepping, windows, doorways, or other features. In one example, the layout rules specify costs associated with different aspects of the layout, with any precluded features being allocated a prohibitively high cost, meaning that in practice a block layout including such arrangements would not be selected for use. However, this is not essential, and alternatively binary rules might be used to prevent some block layouts being considered.

At step 904 the processing device identifies the walls and associated end points, typically based on the construction plan data. The manner in which this is performed will vary depending on how the construction plan is defined, but assuming the construction plan is received as CAD data, the end points of the walls will be listed with other criteria, such as wall thicknesses and height, allowing this to be extracted directly from the CAD data.

At step 906 any intersections are identified as points where the walls intersect, with this being used to identify intersection types at step 908. The intersection types typically include corner, T-junctions, cross junctions, or similar.

At step 910, the processing device selects a next one or more block courses for which block layouts are to be calculated. Whether one or more courses are selected might depend on user defined parameters, such as an available run time, or similar.

At step 912, lists of possible intersection layouts are retrieved for each intersection in the course(s) based on the respective identified intersection types, with a candidate intersection layout, such as the first possible intersection layout in each list, being selected at step 914.

At step 916, a candidate wall block layout is calculated for each wall, typically by back filling the space between intersection block layouts with full blocks where possible, and progressively smaller blocks when full blocks cannot be used. As the walls are typically straight and of limited length, this process is relatively straightforward, although it should be noted that the layout rules could be used to prevent blocks or block joins in the candidate wall block layout being aligned with blocks or block joins in a different course. Thus, in this instance, a position of a partial block might be adjusted in order to avoid such alignment.

A candidate block layout is generated at step 918 based on the selected intersection and calculated wall block layouts before a candidate block layout cost is calculated at step 920, typically by summing the costs associated with each component in the block layout, as defined in the layout rules. For example, at a basic level, this could just include summing a cost associated with each full and each partial block. More typically however the costs will include rules around dependencies of blocks, such as whether one type of block can be positioned adjacent another, alignment of blocks or joins between courses, and the like. This is performed to prioritise features such as structural strength and reduced cost of manufacture.

At step 922 a next intersection in the candidate wall layout is selected, with the processing device determining whether all possible intersection layouts for the selected intersection have been considered in previous iterations at step 924. If so, a next intersection is selected at step 922. Otherwise, at step 926, the processing device selects a next one of the possible intersection layouts from the respective list.

New candidate wall layouts are calculated based on the new intersection block layout at step 928, with this being used to generate a modified candidate block layout at step 930 and associated modified block layout cost at step 932. It will be appreciated that steps 928 to 932 are substantially similar to steps 916 to 920 and these will not therefore be described in any further detail.

At step 934, the processing device compares the candidate and modified block layouts, specifically by comparing the calculated costs to determine whether the modified block layout has a reduced cost, and hence represents an improvement over the candidate block layout which is assessed at step 936. If the modified block layout is an improvement this is used as the new candidate block layout at step 938, otherwise the current candidate block layout is retained.

At step 940 criteria are assessed to ascertain whether further iterations are required. The criteria typically form part of the layout rules, and can define how many iterations are to be performed, a required cost for the candidate block layout, or the like. At step 942, the processing device determines if the iterations have been completed, and if not, the process returns to step 922 to select a next intersection or intersection block layout, and hence generate a new modified block layout. Otherwise, the candidate block layout is saved for later use at step 944.

At step 946 the processing device determines if all courses required to complete the construction plan have been completed, and if not, the process returns to step 910 to select another course or courses. Otherwise, at step 948 block layout data representing the block layout for the entire building is generated, allowing this to be saved for subsequent use. In this regard the block layout data typically includes a block identifier, position and orientation data for each block in the layout, thereby allowing the block layout data to be used in downstream processes. In one example, an optional representation of the block layout could be generated at step 950, allowing this to be reviewed by a user, and optionally modified as required, for example to ensure the final layout is aesthetically appealing.

In another example, the block layout data can be used for designing a block sequence at step 952, and an example of this will now be described in more detail.

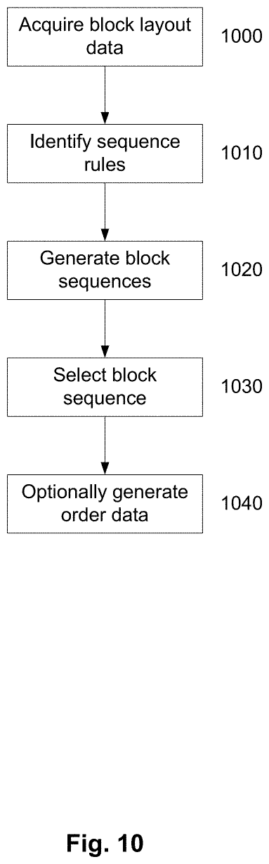

In this regard, an example of a process for designing a block sequence for use in placing blocks during construction will now be described with reference to FIG. 10.

In this example, at step 1000, the processing device acquires block layout data indicative of block layouts for a number of block courses. The block layout data can be acquired in a variety of manners, including receiving block layout data from a CAD package or other software application, using user input commands to define the block layout data, retrieving the block layout data from a database, or the like.

At step 1010, the processing device identifies one or more sequence rules. The sequence rules are typically previously defined and stored in a database or other repository, allowing these to be retrieved as needed. The sequence rules typically specify limitations on the order in which the blocks can be positioned, known as dependencies, and can be defined based on physical limitations associated with equipment placing the blocks, and/or limitations on viable construction.

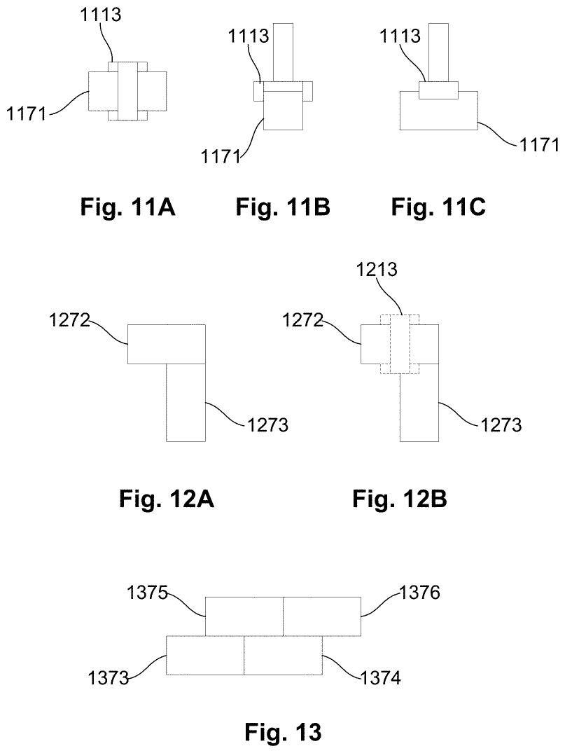

For example, a block laying machine will typically include an end effector configured to grasp the blocks and this can limit how blocks can be placed as will now be described with reference to FIGS. 11A to 11C and 12A and 12B.

In this regard, FIGS. 11A to 11C show how an end effector 1113 can be used to grasp a block 1171, with the location of the end effector effectively generating an exclusion zone adjacent the end effector. For the corner block layout formed from blocks 1272, 1273 in FIG. 12A, this prevents the block laying machine placing the block 1272 if the block 1273 is already in place. Thus, in this instance a dependency is created requiring that the block 1273 is laid after the block 1272, making the block 1272 a parent block, with the block 1273 being a dependent child block.

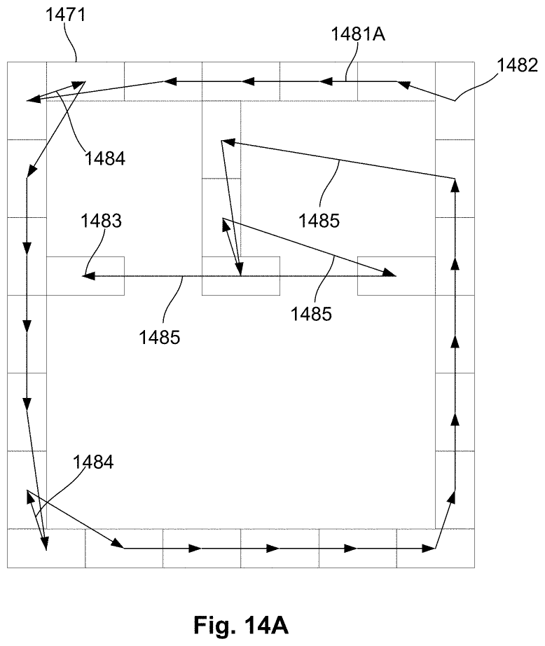

Similarly, in the case of the wall shown in FIG. 13, it is not possible to place the block 1375 before the block 1374, and overhangs as shown by block 1376 are therefore precluded. Thus, in this instance, the block 1375 depends on the block 1374.

It will be appreciated that dependencies may also arise for a variety of other reasons. For example, the block laying machine might have limitations on the handling of different sized blocks, which might require that all partial blocks within a course are laid at the same time. In addition to dependencies, other limitations may arise, such as limitations on operation of the machine, starting positions for the build, or the like.

At step 1020, the processing device generates different block sequences. Each block sequence specifies an order in which blocks should be placed and is generated at least in part based on the sequence rules, thereby ensuring any dependency requirements are met. The sequences can be generated in any manner, such as selecting a next block based on the block that is closest to the previous block, although it will be appreciated that other suitable arrangements could be used.

This process is repeated so a number of different block sequences are created, with one of these being selected for use at step 1030, for example, so as to minimise a distance travelled by a block laying head (i.e. lay head) of the block laying machine. This can then optionally be used to generate sequence or order data, which in one example is in the form of an ordered sequence of blocks, which can be used by a block laying machine in order to construct the building.

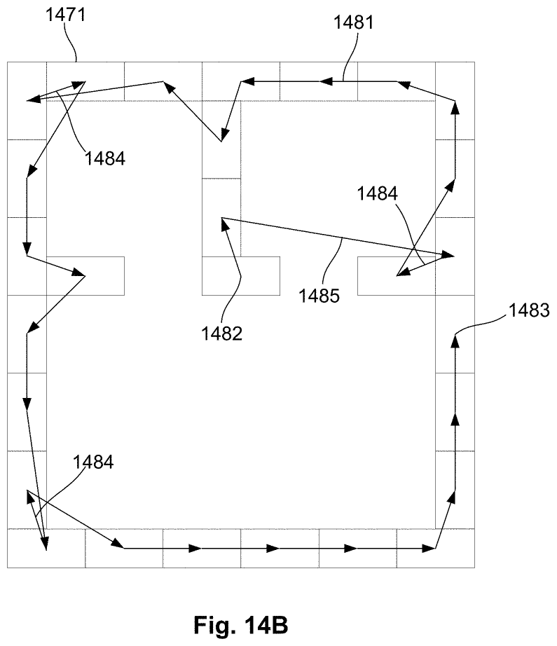

Example block sequences are shown in FIGS. 14A and 14B. In this regard a number of blocks 1471 are laid out to show the outline of a basic building structure, with paths 1481 for the head of the block laying machine to traverse, extending from a start 1482 to an end 1483. Alternative paths 1481 are shown in FIGS. 14A and 14B respectively. These paths illustrate a number of features. For example, the paths include back cross over loops 1484, where a corner block is placed out of sequence to ensure dependency requirements are met, whilst long path segments 1485 show locations where the head of the robot is moving a significant distance without placing blocks.

In the example of FIG. 14A, the outer walls are constructed first, with inner walls then being completed, which results in a number of long path segments 1485, in turn resulting in a longer overall travel path for the for the head of the block laying machine, and hence an increased construction cost. In contrast, in the example of FIG. 14B, blocks are laid based on proximity, rather than focusing completing each wall in turn, meaning inner walls are built concurrently without outer walls. Whilst this results in further loops 1484, there are less long path segments 1485, and as a result the overall path length is shorter, resulting in a reduced construction time.

In any event, it will be appreciated that the above described process operates by generating multiple different block sequences, which are then assessed allowing a block sequence to be selected which is most appropriate, and for example satisfies certain criteria, such as minimising an overall distance of travel for the lay head of the block laying machine, which in turn minimises the costs and time for the construction to be completed. A further advantage of minimising travel of the lay head of the block laying machine is that wear and tear of components is reduced such as drives, bearings and actuators associated with the boom of the machine which typically slews, folds and telescopically extends in order to position the lay head around the slab.

A number of further features will now be described.

In one example, the processing device selects one of the plurality of different block sequences so as to minimize a distance travelled by the head of the block laying robot. However, it will be appreciated that this is not essential, and the sequence may be created in accordance with other priorities, such as constructing the building to allow clear unconstrained operation of the boom of the block laying machine, thereby preventing the boom impacting on a completed part of the structure, or the like.

In one example, the processing device selects one of the different sequences using an optimization algorithm, and in particular an iterative optimization algorithm. In this regard, the total number of possible sequences is large, and is akin to the travelling salesman problem, meaning the number of possible solutions will increase exponentially as the construction plan increases in size. Consequently, it is not generally feasible to calculate and consider all possible block sequences for a building. Instead an iterative optimisation algorithm can used to obtain a solution that is close to optimal, such as a Monte Carlo or Las Vegas algorithms, simulated annealing, or the like. From this it will be appreciated that a wide variety of heuristic approaches to optimization can be used.

In one example, the processing device calculates a sequence cost associated with each of a number of different block sequences and then selects one of the different block sequences using the sequence costs. The cost can be calculated by associating a cost with different considerations, such as by having a cost associated with block dependencies, a distance travelled by a head of a block laying robot, block supply, a change in block type, or the like. In one example, the costs are determined from the sequence rules, so that the relative costs embody the sequence rules, although this is not essential and other suitable arrangements could be used.

In this instance assigning different costs to each of the considerations, allows the relative priority of each of these factors to be easily adjusted, depending on the requirements of the current project. For example, in a scenario where switching between different block sizes is problematic, this can be given a higher cost so that switching of block sizes is minimised in favour of reducing the distance travelled by the head of the block laying robot.

The processing system can then calculate an overall cost for each block sequence and select the sequence with the lowest cost. In one example, this involves using an optimization algorithm to minimise the block sequence cost, with this process optionally being performed using the cost as a measure of fitness, so that block sequences are iteratively modified, with worse block sequences being discarded, and better block sequences being used as a basis for further modified sequences. In another example, some less well performing sequences may be retained to avoid local minima, as implemented in simulated annealing optimisation approaches.

In one example, the processing device iteratively generates block sequences and then selects one of the iteratively generated block sequences. In particular, the processing device generates a candidate block sequence, and then generates a modified block sequences by changing an order of at least one block. The processing device then compares the modified block sequence and the candidate block sequence and selectively updates the candidate block sequence with the modified block sequence depending on results of the comparison. This generally occurs if the modified block sequence is better than the candidate block sequence, and in particular has a lower cost than the candidate block sequence.

Thus, in this example, any worse modified block sequences are discarded, with the processing device trying multiple different block sequences over multiple different iterations. This typically continues until one or more criteria are met, such as a defined total number of iterations have been performed or the candidate block sequence has not been updated for a defined number of iterations, at which point the candidate block sequence is used as the block sequence.

The number of iterations performed will vary depending on the preferred implementation and can range from a single iteration, through to many iterations, depending on the level of refinement required. For example, if designs are planned months in advance, the algorithm can be configured to find an optimal solution, whereas if the design is required in a short time frame, then an optimal design might be sacrificed for speed. This latter case might arise if an issue arises during construction and the block sequence needs to be recreated, for example if blocks are not available in a required order, or if external factors mean a portion of the structure must be constructed out of order. In this instance, a single or small number of iterations could be performed to generate a new block sequence, which while this may not be as optimal, can allow construction to restart in a shorter time frame, which ultimately might prove more cost effective.

The block sequences are typically generated by identifying distances between each block and each other block and then generating the block sequences using the distances, and in one preferred example by ordering blocks based on their relative proximity. In this regard, it will be appreciated that the distance refers to the physical separation of centres of the blocks in the block layout. In one example, a candidate block sequence can be generated by determining a current block and then selecting a next block in the block sequence using the distances and the sequence rules. Specifically, this typically involves selecting the nearest block to the current block, unless this cannot be selected by virtue of a dependency on another block, which has not yet been placed. In this instance, the next nearest block, or the parent block in the dependency can be selected instead. This process is then repeated with the next block as the current block, so that this progresses through each block in turn until all blocks are completed, and a candidate block sequence has been generated.

In this example, it will be appreciated that at the start of the candidate block sequence, all of the blocks can typically be ordered adjacent their nearest neighbour based on the distance. However, towards the end of the sequence, blocks might not be able to be ordered adjacent a nearest block due to this being included earlier in the sequence, which in turn leads to longer path segments 1485, similar to those described above. Accordingly, the processing device can generate a modified block sequence by selecting one of a pair of adjacent blocks based on a distance between the adjacent blocks, then reordering one or more of the selected blocks. Thus, the processing device can select adjacent blocks in the sequence having a greatest distance between them, and then reorder one or more of these, for example to place them in the sequence adjacent a nearest neighbour. In this instance, the relative position of these blocks in the sequence would be fixed and the sequence regenerated, thereby creating the modified candidate block sequence.

Thus, the processing device iteratively generates block sequences by changing positions of the blocks in sequence based on the distance to other blocks, then comparing the modified block sequence and the candidate block sequence and selectively updating the candidate block sequence with the modified block sequence depending on results of the comparison. This generally occurs if the modified block sequence is better than the candidate block sequence, and in particular has a lower cost than the candidate block layout.

Thus, in this example, any worse modified block sequences are discarded, with the processing device trying multiple different block sequences over multiple different iterations. This typically continues until one or more criteria are met, such as a defined total number of iterations have been performed or the candidate block sequence has not been updated for a defined number of iterations, meaning there is less chance of further improvement, at which point the candidate block sequence is used as the block sequence.

The number of iterations performed will vary depending on the preferred implementation and can range from a single iteration, through to many iterations, depending on the level of refinement required. For example, if designs are planned months in advance, the algorithm can be configured to find an optimal solution, whereas if the design is required in a short time frame, then an optimal design might be sacrificed for speed.

As mentioned above, the sequence is generated in accordance with sequence rules, which can be used for example to embody dependencies between the blocks. In another example, sequence rules can be dependent on a block sequence of an adjacent block course. In this regard, it will be appreciated that the first block in a sequence of an upper course should advantageously be provided proximate a final block in a sequence of a lower course, thereby avoiding the need for the head of the block laying machine to travel significant distances between courses.

In this instance, the constrained starting point for the upper course may result in a significant impact on the sequence cost of the upper course, hence resulting in a non-optimal overall sequence. Accordingly, whilst optimisation can be performed on individual courses, in another example, each block sequence is created for two or more block courses, thereby helping improve the efficiency of the resulting sequence. Multiple block sequences can then be generated so as to generate an overall sequence for each of a plurality of block courses in a construction. In this way, the methods described herein may allow multiple courses to be constructed simultaneously, whereas previously building was carried out in a course by course manner.

As previously mentioned, the block sequences can include blocks having different block types, such as blocks for internal walls, blocks for external walls, full blocks, or part blocks such as quarter blocks, half blocks or three quarter blocks.

It will be appreciated that the sequencing process can be used in conjunction with the above described layout process, so that the processing device can acquire plan data indicative of a construction plan, identify walls and intersections within the construction plan, identify a number of possible intersection layouts for each intersection, generate different block layouts, each block layout including a combination of intersection layouts including a possible intersection layout for each intersection and at least one wall layout for each wall, the wall layouts being generated based on the combination of intersection layouts and then select one of the different block layouts. This can be used to generate block layout data, which is used by the sequencing process.

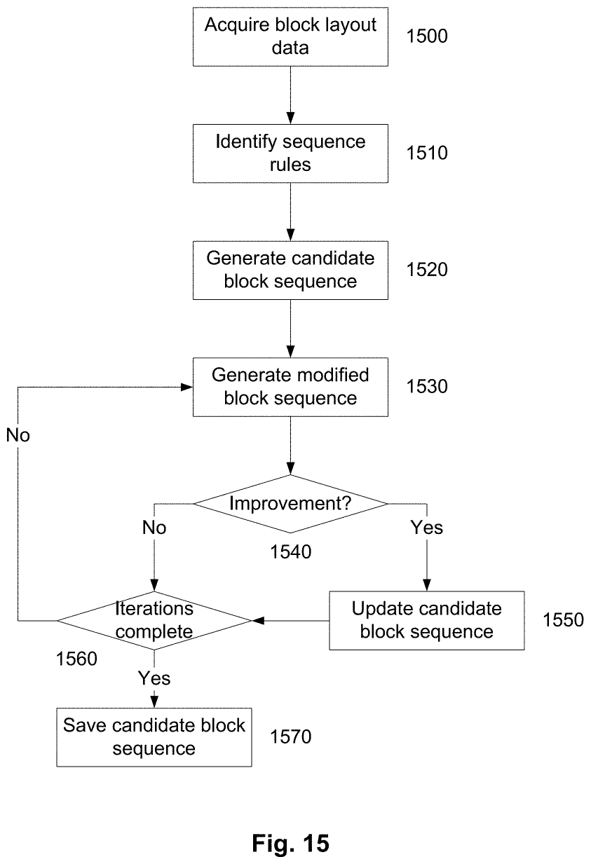

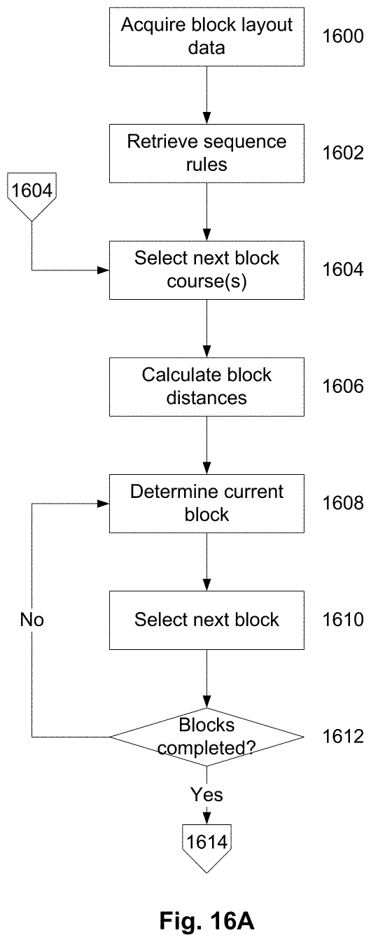

A further example of a method for designing a block sequence for use in block placement during construction will now be described with reference to FIG. 15.

In this example, at step 1500, block layout data is acquired, for example by having performed the layout process described above. At step 1510, the processing device identifies sequence rules, defining restrictions on how blocks can be ordered within the sequence, for example based on dependencies required in order to allow the block laying machine to successfully place blocks.

At step 1520, the processing device generates a candidate block sequence, typically by selecting a block, identifying the nearest block that satisfies the sequence rules, and then repeating this until all blocks are included in the candidate block sequence.

At step 1530, a modified block sequence is created by selecting adjacent blocks in the sequence that have a greatest physical spacing in the block layout, and then reordering these blocks and generating a new sequence. The processing device compares the modified and candidate block sequence to determine if there is any improvement at step 1540. This will typically involve calculating a cost for each block sequence, based on the cost of individual components such as the distance travelled by the head of the block laying machine, and then comparing the costs, with the lower cost representing the better of the candidate and modified block sequences.

If the modified block sequence represents an improvement, then the current candidate block sequence is replaced with the modified block sequence at step 1550, otherwise the current candidate block sequence is retained.

At step 1560, the processing device determines if the iterations are complete, for example if a required number of iterations have been completed, or the current candidate block sequence is deemed acceptable, and if not, the process returns to step 1530 to generate a new modified block sequence. Otherwise, the candidate block sequence is saved for later use, for example in controlling a block laying machine.

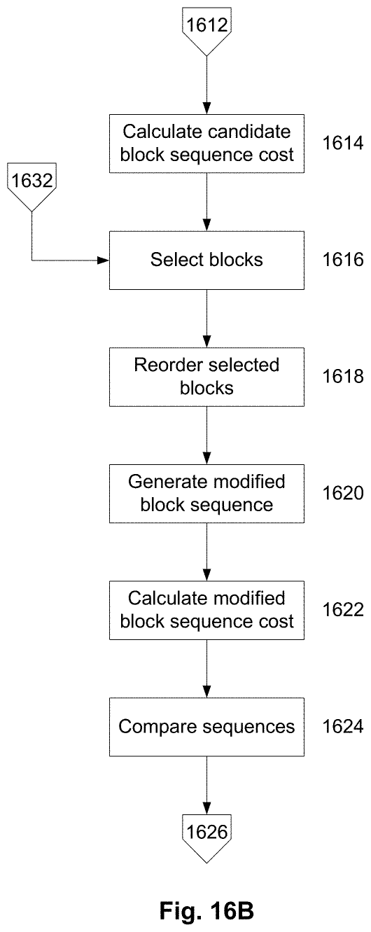

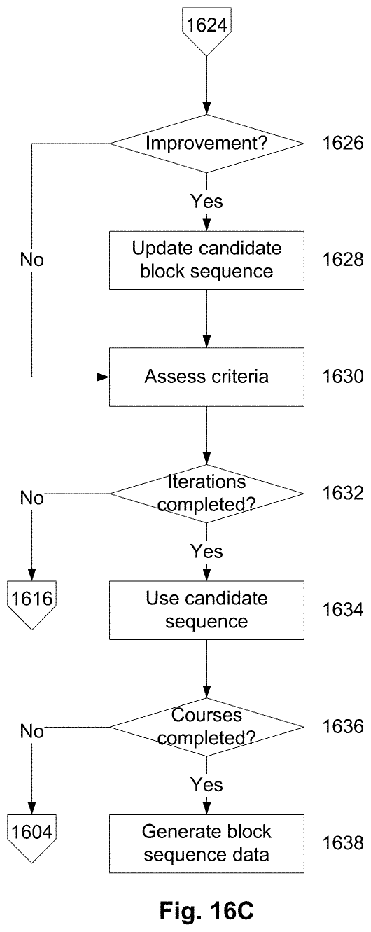

A further specific example of a method for designing a block sequence for use in block placement during construction will now be described with reference to FIGS. 16A to 16C.

In this example, the processing device acquires block layout data at step 1600. The block layout data represents the block layout for an entire building and is generated as described above. The block layout data typically includes a block identifier, coordinates and rotation for each block in the layout, thereby allowing the block layout data to be used to position each block during the build. The manner in which the block layout data is acquired will vary depending on how it is created, but typically this is received from CAD software that includes a plug-in, which performs the block layout design process.

At step 1602, the processing device retrieves sequence rules, which can be used to control the sequence design. The sequence rules can define limitations on how blocks are ordered within the sequence, and a wide range of limitations could be defined. For example, the sequence rules could place restrictions on the order in which blocks can be positioned during the build. This could be based on dependencies, such as the need to place a parent block, before a dependent child block is positioned, or could include limitations on the supply of blocks, for example requiring that all full blocks are positioned first, or that all partial blocks are positioned sequentially. In one example, the sequence rules specify costs associated with different aspects of the block sequence, with any precluded features, such as dependencies being allocated a prohibitively high cost, meaning that in practice a block sequence breaching dependency requirements would have such a high cost it would not be selected for use. However, this is not essential, and alternatively binary rules might be used to prevent some block sequences being generated or considered.

At step 1604 the processing device selects a next course or courses for which a sequence is to be generated, before calculating block distances between each pair of blocks in the course(s) at step 1606. The manner in which this is performed will vary depending on how the block layout data is defined, but will typically involve calculating a physical distance between the blocks based on the coordinates provided in the block layout data.

At step 1608 a current block is determined. On the initial iteration, the current block is a starting block and could be selected at random, based on a last block positioned on an earlier course, or could be a block having a shortest distance to an adjacent block. A next block is then selected at step 1610, with the next block being the block nearest the current block. At step 1612, it is assessed if all blocks in the course(s) are included in the sequence, and if not the process returns to step 1608, with the next block now being set as the current block, and a nearest block selected based on the nearest neighbour. This is repeated until all blocks in the course(s) are included, at which point the sequence of blocks represents a candidate block sequence. At step 1614, the processing device calculates a candidate block sequence cost, typically by summing the costs associated with each component in the block sequence, as defined in the sequence rules. For example, at a basic level, this could just include summing a cost associated with the distance between the blocks in the sequence, which represents the overall travel requirement for the head of the block laying machine.

At step 1616 two or more blocks in the candidate block sequence are selected, typically based on adjacent blocks in the sequence that have the greatest physical separation, and hence represent long path segments 1485 similar to those described above. At step 1618, the processing device re-orders one or more of the selected blocks, for example placing the block next to a nearest physical neighbour, before generating a modified block sequence at step 1620 and associated cost at step 1622. This is achieved by effectively repeating the process performed in steps 1608 to 1614 above, but with a constraint on the position of the reordered block(s) within the sequence.

At step 1624, the processing device compares the candidate and modified sequences, specifically comparing the calculated costs to determine whether the modified sequence has a reduced cost compared to the candidate sequence, and hence represents an improvement. If the modified block sequence is determined to be an improvement at step 1626, this is used as the new candidate block sequence at step 1628, by replacing the current candidate block sequence with the modified block sequence. Otherwise the current candidate block sequence is retained.

At step 1630 criteria are assessed. The criteria typically form part of the sequence rules, and can define how many iterations are to be performed, a required cost for the candidate block sequence, or the like. This is used to control the number of iterations performed, in turn controlling the time spent by the optimisation process.

At step 1632, the processing device determines if the iterations have been completed, and if not, the process returns to step 1616 to select different blocks for generating a different modified block sequence. Otherwise, the candidate block layout is saved for later use at step 1634.

At step 1636 the processing device determines if all courses required to complete the construction plan have been completed, and if not, the process returns to step 1604 to select one or more further courses. Otherwise, at step 1638 block sequence data representing the block sequence for the entire building is generated, allowing this to be saved for subsequent use. In this regard the block sequence data typically includes an ordered list of block identifiers, which can then be used in conjunction with the block layout data to allow individual blocks to be provided at a specific location in a specific sequence. Thus, in conjunction, the block layout and block sequence can be provided to a control system 230 of a block laying machine, allowing the blocks to be placed as required during construction.

In this regard, there is also provided a method for controlling a block laying machine to construct a building, the block laying machine including a block laying head comprising a robot arm and end effector for placing blocks, the block laying head mounted at the end of a boom for positioning the head, the method including in the control system 230 receiving block layout data generated according to the previously described method and controlling at least one of the boom and robot arm so as to allow the end effector to position blocks according to the block layout data.

Further, the method may include in the control system 230 receiving block sequence data generated according to the previously described method and controlling at least one of the boom and robot arm so as to allow the end effector to position blocks according to the block sequence data. In this regard, it is to be appreciated that in at least some examples, the block sequence data results in the block laying machine constructing the building by laying blocks of at least some courses simultaneously. In other words, instead of laying every block of one course before commencing laying of blocks in the next course (i.e. course by course construction), blocks in two or more courses may be laid sequentially so that in effect two or more courses of blocks are constructed in parallel.

Accordingly, it will be appreciated that the above described process operates by utilising optimisation processes to optimise the block layout and/or the block sequence, which is used when laying the blocks. These processes are typically performed independently, but this is not essential, and in a further example, the optimisation process is performed collectively, so that the layout and sequence are optimised in a single process.

Another feature of the block layout design process is the use of a grid system utilised by the processing device in generating possible block layouts. The grid system uses a grid comprising square grid elements having a length x and width y, whereby x=y. The dimensions of the grid elements are indicative of a minimum block dimension. In this regard, it is to be appreciated that the minimum block dimension is typically its width such that each grid element or pixel has the same dimensions as the width of the block type used to construct a wall segment of the building.

Typically, wall segments are extracted from the construction plan data and overlayed onto the grid so that each wall segment is indicative of a number of grid elements. Different block layouts are then generated by fitting different combinations of blocks onto the grid elements associated with each wall segment. The blocks used to populate a wall segment are modular in that their length is divisible by their width. This ensures that a wall can be populated with a combination of full blocks and part blocks (each part block also having a length divisible by the width). This modularity concept also ensures that cavities spaced evenly along the length of the block will be aligned from the bottom course through to the top course regardless of the combination of full or part blocks used in each course. These cavities may be used to run conduits and building services through blocks in the wall.

Once a block layout for the building is selected for use, the grid populated by blocks is converted into actual dimensions using the width and length of the selected block type and this allows the position coordinates of each block in the grid to be determined.

An advantage of using the grid system to populate blocks in wall segments of a building plan is that any type of modular block may be used to construct the building. Previously, the dimensions of a particular block were hard coded into the block layout design software and it was not possible to selectively choose any other type of modular block for use in populating the wall segments and generating block layouts.

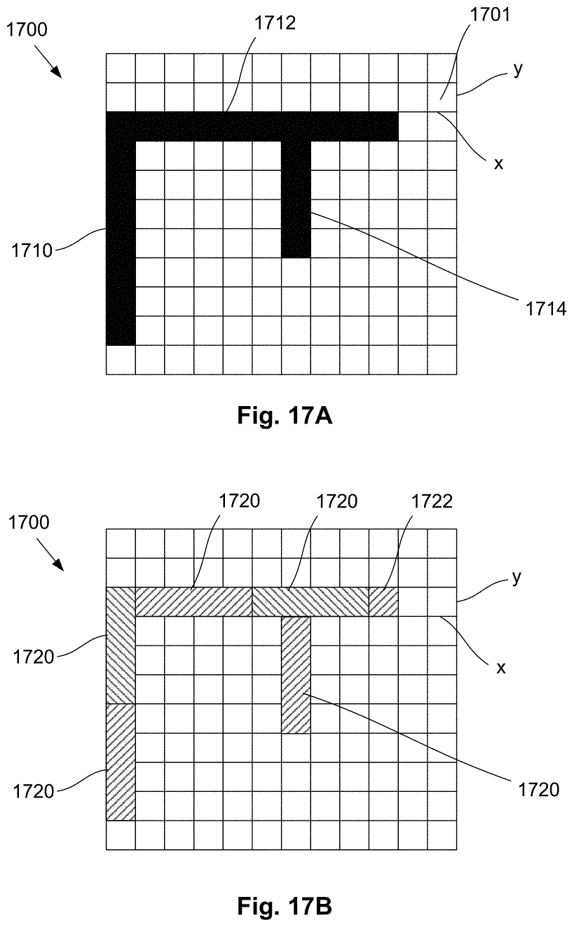

Referring now to FIG. 17A, a grid 1700 is shown comprising a plurality of grid elements or pixels 1701 having x and y dimensions for length and width, where x=y. Part of a construction plan is shown overlayed onto the grid 1700, the plan having wall segments 1710, 1712, and 1714. In FIG. 17B, a schematic illustration is provided of a block layout that has been determined by the processing device using a block having a length to width ratio of 4:1. The algorithm has used five full blocks 1720 and one quarter block 1722 to populate the wall segments using the grid 1700. The position coordinates of each block can be determined using the actual dimensions of the grid which in one example may be obtained by calling a third party class that acts to convert wall sketches to the grid and vice versa.

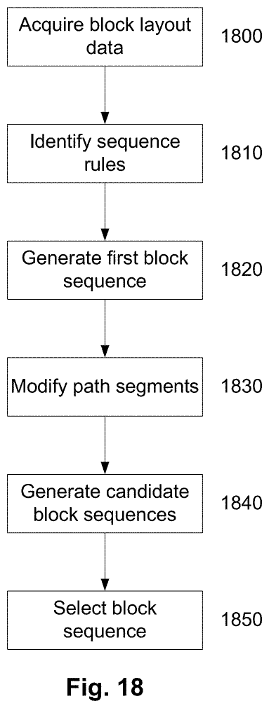

A further example of a method for designing a block sequence for use in block placement during construction will now be described with reference to FIG. 18.

In this example, at step 1800, block layout data is acquired, for example by performing the layout process described above, retrieving a previously generated layout, or the like. At step 1810, the processing device identifies sequence rules. Initially, the sequence rules typically only define restrictions on how blocks can be ordered within the sequence, for example based on dependencies required in order to allow the block laying machine to successfully place blocks. The sequence rules can be generated based on an understanding of operation of the machine and the requirements associated with wall building, such as ensuring adequate support of higher courses, and may be input manually, generated from the block layout or retrieved as part of the block layout data, depending on the preferred implementation.

At step 1820, the processing device generates a first block sequence, typically by selecting a block, identifying the nearest block that satisfies the sequence rules, and then repeating this until all blocks are included in the first block sequence.

At step 1830, the processing device modifies path segments, typically by identifying the longest path segments, and then altering these so that a shorter path segment length is created. Following this, the processing device recalculates remaining parts of the sequence, for example using a nearest block approach, at step 1840 to thereby generate a second candidate block sequence.

Steps 1830 and 1840 can be repeated a number of times, by modifying different path segments, with this being used to generate multiple second candidate block sequences, which in turn allows the processing device to select the block sequence using one of the second candidate block sequences at step 1850.

Accordingly, it will be appreciated that this provides a further alternative approach to designing a block sequence, which again generates multiple candidate block sequences using sequence rules, and then selects one of the multiple candidate block sequences for use, for example by selecting a block sequence that defines a shortest overall path length.

A number of further features will now be described.

In one example, the processing device generates the first block sequence using a nearest neighbour approach, which is a coarse method to achieve a block sequence that can act as a reasonable starting point for further refinement. In this example, the processing device, starting with a block, identifies a nearest block that is not assigned to the block sequence, before generating a path segment extending from the block to the nearest block. This process is then repeated with the nearest block as the source block for the next path segment, and continues until all blocks are present in the first block sequence.

The nearest neighbour process is performed taking into account dependencies, so that a nearest block is ignored if it does not meet dependency requirements. In one example, this is achieved using a hierarchy of sequence rules, which includes a closest neighbour sequence rule and dependency rules. In this case, the closest neighbour sequence rule causes a path segment to extend from a block to a next nearest block, whilst the dependency rules are associated with one or more blocks and define a specific ordering dependency for the blocks. In this case, the rules are processed so that the dependency rules override the closest neighbour rules, meaning a closest neighbour is selected unless this breaches the dependency rule.

Once a first block sequence has been generated, the processing device can evaluate path segments in the first block sequence and generate a number of second candidate block sequences by modifying one or more path segments based on results of the evaluation. The processing device typically evaluates the path segments based on whether or not they satisfy certain criteria, and in one particular example, evaluates the path segments with a view to minimizing the overall path length.

To achieve this, the processing device evaluates path segments in the first block sequence to identify one or more bad path segments, each bad path segment extending from a block to a next block and having a path length greater than a distance from the block to a number of closer neighbouring blocks. The processing device then generates a second candidate block sequence by modifying a bad path segment so that anew path segment extends from the block to a different next block. Thus, in this instance, the processing device alters the path segments, so that new path segments are generated that are shorter than the bad path segment.

In one particular example, the evaluation involves calculating a path segment length from a block to a next block and calculating a number of closer blocks that are separated from the block by a distance shorter than the path segment length. Bad path segments are then identified based on the number of closer blocks associated with the path segment. For example, the number can be used to generate an index, with a higher number indicating that the path segment is worse.

Following this, the processing device can then order or rank the bad path segments based on the number of closer neighbouring blocks, allowing the processing device to prioritize the path segments that are modified, for example by progressively modifying the bad path segments based on the ordering. Thus, a worst bad path segment could be modified and used as the basis for a second candidate block sequence, with this being repeated for subsequent bad path segments or different combinations of bad path segments, to thereby generate multiple second block sequences. This could be continued until criteria are satisfied, such as all bad path segments above a certain length or index value have been modified, and/or a certain number of second candidate block sequences generated.

In one example, in order to modify the bad path segments, this is achieved by generating a bad path segment sequence rule associated with each bad path segment. The bad path segment sequence rule precludes use of the bad path segment, typically by requiring that the two blocks in the bad path segment are instead constrained to being connected to other blocks, such as nearest blocks. In this instance, the processing device generates second candidate block sequences using the sequence rules so that the dependency rules override the bad path segment rules and the bad path segment rules override the nearest neighbour rule, thereby effectively forming a hierarchy of sequence rules.

Once multiple second block sequences have been created, the process typically involves selecting a second candidate block sequence with a shortest path length. This can then be used as the block sequence, or can undergo additional refinement. However, it will be appreciated that in the event the first block sequence is shorter than the second block sequences, this could alternatively be used.

In one example, additional refinement is performed by generating a number of third candidate block sequences by modifying the path in the second block sequence and then generating the block sequence using one of the third candidate block sequences.

The nature of the refinement can vary depending on the preferred implementation, but in one example is achieved by allowing the path to be created so that at least one new path segment extending from a block in the third block sequence is longer than the path segment extending from the same block in the second block sequence. In effect this is a variation on the nearest neighbour approach that allows path segments to join to non-nearest neighbours, which can result in some overall reductions in path length.

In one example, this is achieved by using an alternative path sequence rule which allows the path segment to extend between non-nearest neighbour blocks. In this instance, the processing device can generate third candidate block sequences using the sequence rules so that the alternative path sequence rule overrides the nearest neighbour rule for at least some of the blocks. By implementing the alternative path sequence rule for different blocks within the block layout, this allows a range of different third candidate block sequences to be generated.

Again, the processing device can then generate the block sequence by selecting a block sequence having a shortest path, and whilst this is typically a third candidate block sequence, this is not essential and second or first block sequences could alternatively be used.

Similarly, whilst the shortest block sequence could be used, more typically these undergo additional refinement. In one example, this process involves having the processing device generate a number of fourth candidate block sequences by re-routing at least part of a path in the third block sequence and then generating the block sequence using one of the fourth candidate block sequences.

The re-routing process could be performed in any manner, but is typically achieved by re-routing a bad path segment, whilst maintaining the shape of the majority of the path. Thus, this process typically involves evaluating path segments in the third block sequence, to identify bad path segments, and then generating the number of fourth candidate block sequences by re-routing one or more path segments based on results of the evaluation.

In contrast to the previous assessment of bad path segments, this typically involves more than just examining the overall length, but also considers the relationship to the remainder of the path. To implement this, the processing device evaluates path segments to identify path segments extending from a block to a next block and having a path length greater than a distance from the block to a downstream next block which is in the path downstream of the path segment. In this case, a fourth candidate block sequence can be generated by re-routing the bad path segment so that a re-routed path segment extends from the block to the downstream next block and a path section between the next block and the downstream next block is substantially unaltered, thereby preserving parts of the path that are already substantially optimal.

This is typically performed by generating the fourth candidate block sequences using the alternative path sequence rules, the re-routed path segment and the path section, in other words, using an approach similar to that described above with respect to the third candidate block sequences, albeit with the path already partially defined and with bad segment re-routes defined.

At the end of this process, the block sequence that is used is determined by selecting one of the second, third and fourth candidate block sequences with a shortest path length.

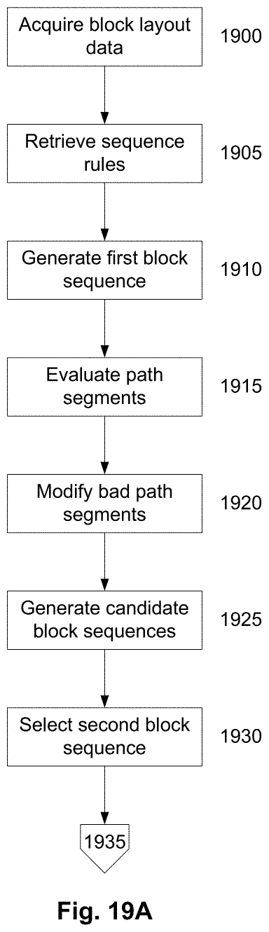

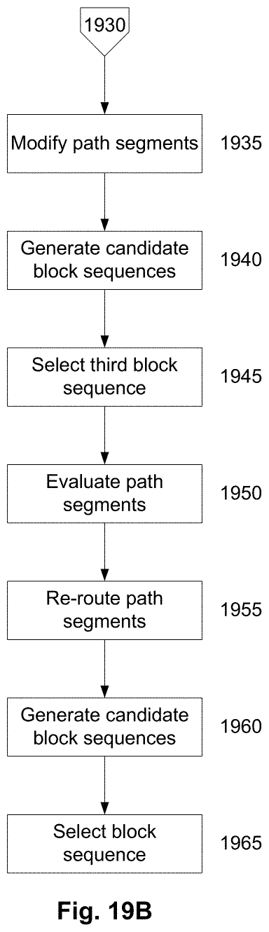

An overview of this multiple stage process will now be described with reference to FIGS. 19A to 19B.

In this example, at step 1900 block layout data is acquired, with sequence rules being determined at step 1905. These steps can be performed in a manner similar to steps 1800 and 1810 described above. At step 1910, the processing device generates a first block sequence using a nearest neighbour approach, before evaluating the path segments at step 1915, to thereby assess bad path segments.

At step 1920 the bad path segments are modified, by creating an additional sequence rule to override the nearest neighbour approach for the bad path segments, with this rule being used to generate second candidate block sequences at step 1925. A shortest one of these is selected at step 1930 and used to perform further refinement.

Specifically, at step 1935 path segments are modified by creating a rule to override the nearest neighbour approach, so that different paths can be considered, allowing third candidate block sequences to be generated at step 1940. A shortest one of these is selected at step 1945 and used to perform further refinement.

In particular, at step 1950, the processing device evaluates path segments, to identify bad segments which could be re-routed to a nearer downstream portion of the path. The paths are re-routed at step 1955, with fourth candidate block sequences being generated at step 1960 using the alternative path sequence rules and the re-routed path. A final block sequence can then be selected for use at step 1965.

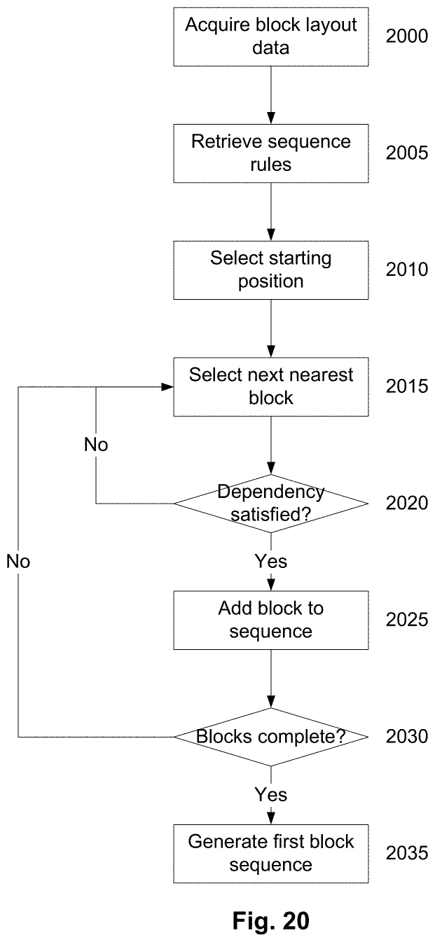

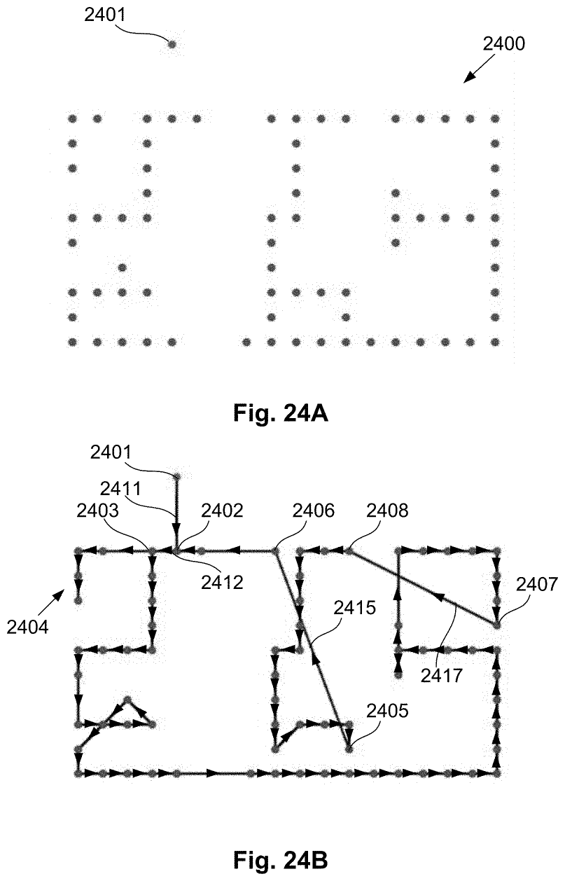

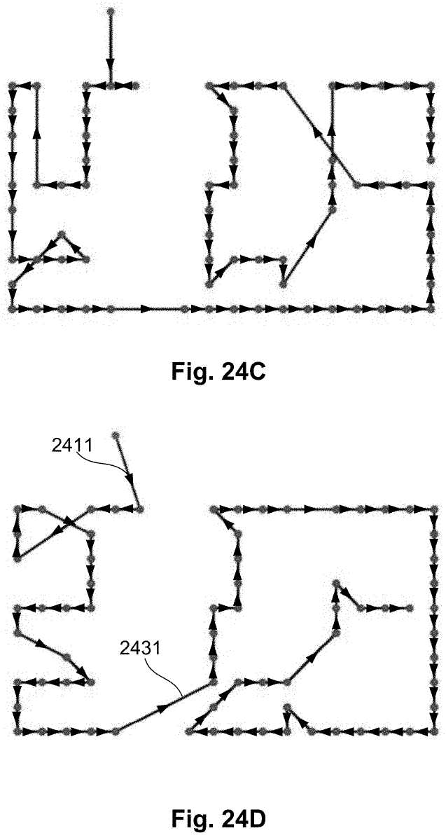

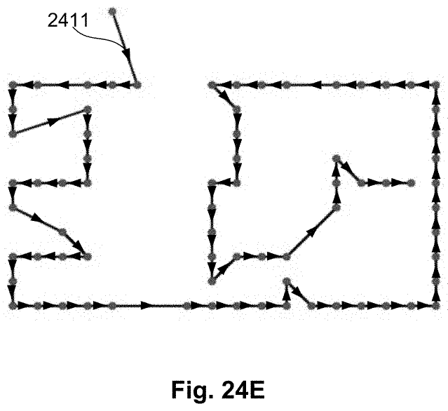

Each of these four stages will now be described in further detail with reference to FIGS. 20 to 23, and the example layouts and paths of FIGS. 24A to 24E.

An example of the process for generating a first block sequence will now be described with reference to FIG. 20.

In this example, at step 2000 block layout data is acquired. An example of this is shown in FIG. 24A, with the dots 2400 representing block positions and the dot 2401 a starting position for the robot lay head. Sequence rules are retrieved at step 2005, and a starting position 2401 selected at step 2010. The starting position may correspond to a block position, or may be independent of a block position, depending on the preferred implementation.

At step 2015 a next nearest block 2402 is selected as shown in FIG. 24B. In the event there are multiple blocks at a similar distance, one of these is selected as the next nearest block 2402 randomly. Once a next nearest block 2402 is selected dependency rules are checked at step 2020, to ensure the next nearest block 2402 can be positioned before other blocks. If the dependency rule is not satisfied an alternative next nearest block is selected by returning to step 2015, otherwise the block is added to the sequence at step 2025, thereby creating a path segment 2411.

At step 2030 it is determined if all blocks in the layout are completed, and if not, the process returns to step 2015 to select a next nearest block 2403 to thereby generate a path segment 2412. Otherwise, the first block sequence is created at step 2035, and an example of this completed first block sequence is shown in FIG. 24B.

It is noted that there are two long path segments 2415, 2417 extending from source blocks 2405, 2407 to destination blocks 2406, 2408, where no blocks are laid, and that also the path returns to pass over path segment 2412 to allow the blocks 2404 to be added. The path has an effective length of 3117 in arbitrary units, and this will be used as a point of comparison for lengths of subsequent block sequences.

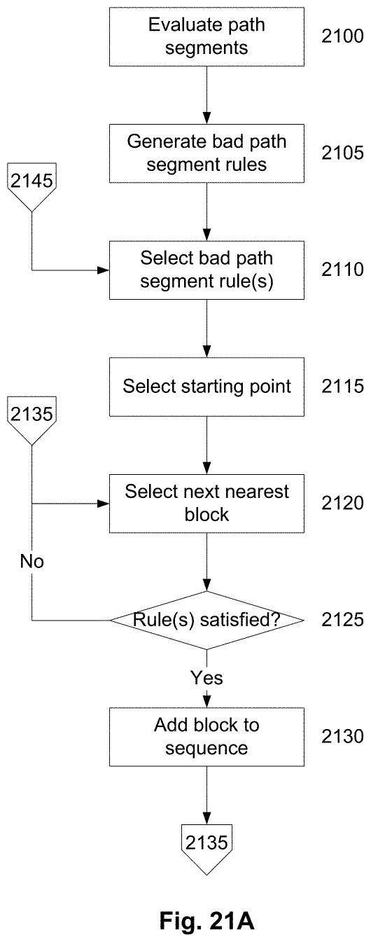

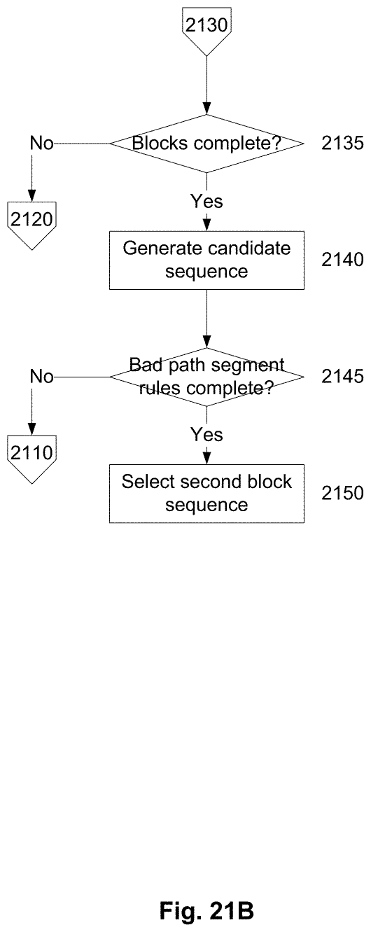

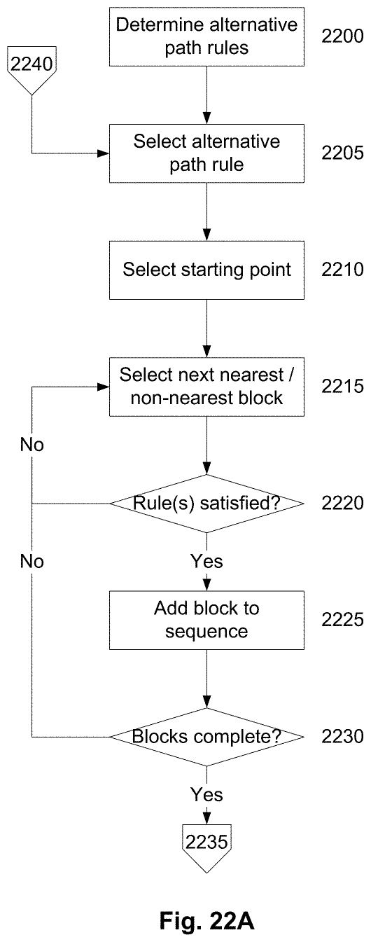

An example of the process for generating a second block sequence will now be described with reference to FIGS. 21A and 21B.

In this example, at step 2100 path segments are evaluated. To do this, in one example, the processing device builds a list of closest blocks for each block. It then checks one by one, the path segments in the first block sequence and compares the path segment length with the list of closest blocks to the starting block in the path segment to identify a number of blocks that are closer than the destination block of the path segment. This is used to work out an index, with a value of “0” meaning that the path segment uses the shortest distance between blocks and a high index value meaning there is a larger number of closer blocks, and hence that the path segment is unduly long, as per the path segments 2415, 2417.

At step 2105, bad path segment rules are generated that override the bad path segments, such as path segments 2415, 2417, and force path segments from the source blocks 2405, 2407 to nearer blocks. Multiple bad path segment rules are typically generated with one or more of these being selected at 2110, to create a respective second candidate block sequence.

At step 2115 a starting point is selected, and a next nearest block 2402 selected at step 2120. Sequence rules, including dependency and bad path segment rules are checked at step 2125, to ensure these are satisfied, for example to avoid the destination block being subject to dependency or bad path segment limitations. If the rules are not satisfied an alternative next nearest block is selected by returning to step 2120, otherwise the block is added to the sequence at step 2130, thereby creating a path segment.

At step 2135 it is determined if all blocks in the layout are completed, and if not, the process returns to step 2120 to select a next nearest block to thereby generate another path segment. Otherwise, a second candidate block sequence is created at step 2140.

The process then assesses whether all the bad segment rules are complete at step 2145, and if not the process returns to step 2110, allowing different rules to be selected, to thereby generate an alternative second candidate block sequence. Once all the rules and/or a sufficient number of rules and/or combinations have been considered, a shortest block sequence is selected as the second block sequence, and an example of a completed second block sequence is shown in FIG. 24C.

It is noted that in this example, whilst there are some longer path segments, these are significantly shorter than the two long path segments 2415, 2417 in the first block sequence. Additionally, the path no longer returns to pass over path segment 2412 to allow the blocks 2404 to be added. This path has an effective length of 2840 arbitrary units, and therefore represents a significant improvement over the first block sequence.

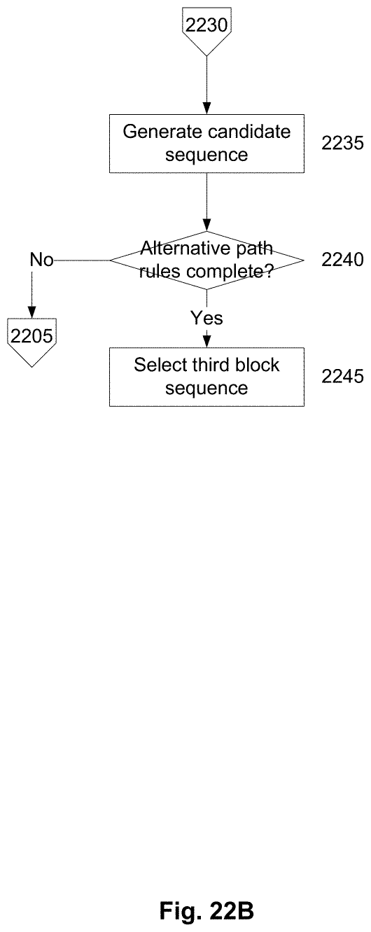

An example of the process for generating a third block sequence will now be described with reference to FIGS. 22A and 22B.

In this example, at step 2200 alternative path rules are created to fine tune the path. This works by going through every point in the path and trying a few new rules other than the nearest neighbour rule. In one example, the alternative path rules allow the path to try a number of closest blocks around each block, rather than just the closest, which can result in a lower overall path length. At step 2205, alternative path rules are selected for one or more blocks. In one example, the alternative path rules may force the path to try a fixed percentage of closest blocks around each block to determine whether a shorter overall path length can be obtained. For example, paths using 25% of the closest blocks around each block may be simulated in an effort to balance overall reduction in path length with computational time. The fixed percentage may be adjusted as necessary.

At step 2210 a starting point is selected, and a next nearest or non-nearest block selected at step 2215. Sequence rules, including dependency and bad path segment rules are checked at step 2220, to ensure these are satisfied, for example to avoid the destination block being subject to dependency or bad path segment limitations. If the rules are not satisfied an alternative next nearest or non-nearest block is selected by returning to step 2215, otherwise the block is added to the sequence at step 2225, thereby creating a path segment.

At step 2230 it is determined if all blocks in the layout are completed, and if not, the process returns to step 2215 to select a next nearest or non-nearest block to thereby generate another path segment. Otherwise, a third candidate block sequence is created at step 2235.

The process then assesses whether all the alternative path rules have been considered for a sufficient number of blocks at step 2240, and if not the process returns to step 2205, allowing rules to be implemented for different blocks, to thereby generate an alternative third candidate block sequence. Once sufficient number of blocks and/or combinations of blocks have been considered with the alternative path rules, a shortest block sequence is selected as the third block sequence, and an example of a completed third block sequence is shown in FIG. 24D.

It is noted that in this example, the starting path segment 2411 has changed resulting in a reduction in overall path length. Similarly in other parts of the sequence, reordering results in a reduction in overall path length, however, there is still at least one path segment 2431 having a significant length. In this example, the resulting path has an effective length of 2670 arbitrary units, and therefore represents a significant improvement over the second block sequence.

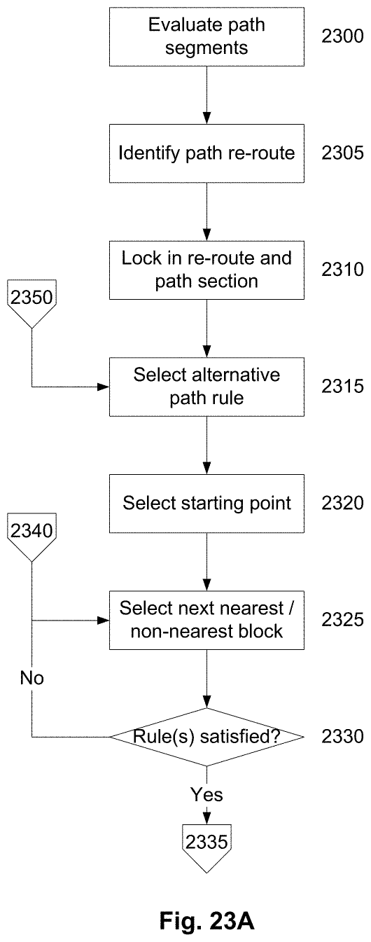

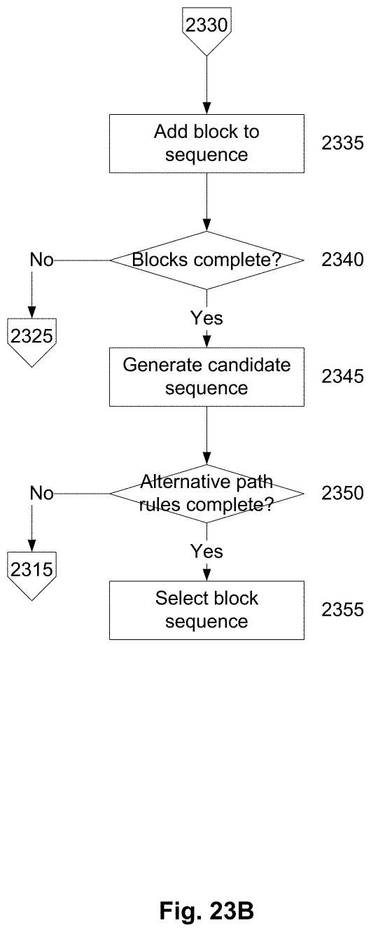

An example of the process for generating a fourth block sequence will now be described with reference to FIGS. 23A and 23B.

In this example, at step 2300 path segments are evaluated to identify bad path segments. To do this, in one example, the processing device can again build a list of closest blocks for each block. It then checks one by one, the path segments in the third block sequence and compares the path segment length with the list of closest blocks to the source block in the path segment to identify a number of blocks that are closer than the destination block of the path segment. This is used to work out an index, with a value of “0” meaning that the path segment uses the shortest distance between blocks and a high index value meaning there is a larger number of closer blocks, and hence that the path segment is unduly long, as per the path segments 2431.

At step 2305, the system examines bad path segments and compares the source and destination blocks to identify if at any stage of the path there is a block closer to these blocks. If so, the processing device creates a re-route and locks in the intervening part of the path (not including the direction) then cuts and paste this section of the path in place of these bad path segments to see if it improves the overall distance of the whole path, by repeating the approach used to generate the third candidate block sequences.

Thus, at step 2315 alternative path rules are selected for one or more blocks. At step 2320 a starting point is selected, and a next nearest or non-nearest block selected at step 2325. Sequence rules, including dependency and bad path segment rules are checked at step 2330, to ensure these are satisfied, for example to avoid the destination block being subject to dependency or bad path segment limitations. If the rules are not satisfied an alternative next nearest or non-nearest block is selected by returning to step 2325, otherwise the block is added to the sequence at step 2335, thereby creating a path segment.

At step 2340 it is determined if all blocks in the layout are completed, and if not, the process returns to step 2325 to select a next nearest or non-nearest block to thereby generate another path segment. Otherwise, a fourth candidate block sequence is created at step 2345.

The process then assesses whether all the alternative path rules have been considered for a sufficient number of blocks at step 2350, and if not the process returns to step 2315, allowing rules to be implemented for different blocks, to thereby generate an alternative fourth candidate block sequence. Once sufficient number of blocks and/or combinations of blocks have been considered with the alternative path rules, a shortest block sequence is selected as the fourth block sequence, and an example of a completed fourth block sequence is shown in FIG. 24E.

In this example, the resulting path has an effective length of 2593 arbitrary units, and therefore represents an improvement over the third block sequence.

Thus, it can be seen in the above described approach that the process starts with a nearest neighbour approach to create an initial first block sequence. The process then iteratively improves on this by progressively introducing rules that modify the process, with the rules being generated based on an assessment of bad path segments, and to allow for variation of the path from the nearest neighbour approach. This can result in a substantial improvement over the initial block sequence created, but minimises the processing time required compared to other approaches for generating block sequences.

Throughout this specification and claims which follow, unless the context requires otherwise, the word “comprise”, and variations such as “comprises” or “comprising”, will be understood to imply the inclusion of a stated integer or group of integers or steps but not the exclusion of any other integer or group of integers. As used herein and unless otherwise stated, the term “approximately” means±20%.

Persons skilled in the art will appreciate that numerous variations and modifications will become apparent. All such variations and modifications which become apparent to persons skilled in the art, should be considered to fall within the spirit and scope that the invention broadly appearing before described.

What is claimed is:

1) A method for designing block layouts for use in block placement during construction, the method including, in one or more electronic processing devices:
a) acquiring plan data indicative of a construction plan;
b) identifying walls and intersections within the construction plan;
c) identifying a number of possible intersection layouts for each intersection;
d) generating different block layouts, each block layout including:
i) a combination of intersection layouts, the combination including one of the number of possible intersection layouts for each intersection; and,
ii) at least one wall layout for each wall, the wall layouts being generated based on the combination of intersection layouts; and,
e) selecting one of the different block layouts.

2) A method according to claim 1, wherein the method includes, in the one or more processing devices, selecting one of the plurality of different block layouts so as to at least one of:
a) minimize a number of blocks used;
b) minimize a number of part blocks used;
c) avoid alignment of blocks in different block courses; and,
d) avoid alignment of block joins in different block courses.

3) A method according to claim 1 or claim 2, wherein the method includes, in the one or more processing devices, selecting one of the different block layouts using an optimization algorithm.

4) A method according to any one of the claims 1 to 3, wherein the method includes, in the one or more processing devices:
a) calculating a block layout cost associated with each of a number of different block layouts; and,
b) selecting one of the different block layouts using the block layout costs.

5) A method according to claim 4, wherein the method includes, in the one or more processing devices, using an optimization algorithm to minimize the block layout cost.

6) A method according to claim 4 or claim 5, wherein the method includes, in the one or more processing devices, calculating the block layout cost using at least one of:
a) a cost associated with a block type;
b) a cost associated with a full block;
c) a cost associated with a part block;
d) a cost associated with an intersection layout;
e) a cost associated with an alignment of blocks in different block courses; and,
f) a cost associated with an alignment of block joins in different block courses.

7) A method according to claim 6, wherein the cost associated with each block is less than the cost associated with each part block.

8) A method according to any one of the claims 1 to 7, wherein the method includes, in the one or more processing devices:
a) iteratively generating block layouts using different combinations of intersection block layouts; and,
b) selecting one of the iteratively generated block layouts.

9) A method according to any one of the claims 1 to 8, wherein the method includes, in the one or more processing devices:
a) generating a candidate block layout;
b) iteratively:
i) generating a modified block layout by changing at least one intersection layout in the candidate block layout;
ii) comparing the modified block layout and the candidate block layout; and,
iii) selectively updating the candidate block layout with the modified block layout depending on results of the comparison; and,
c) when one or more criteria are met, selecting one of the different block layouts by using the candidate block layout.

10) A method according to claim 9, wherein the method includes, in the one or more processing devices, generating a candidate block layout by:
a) selecting a candidate intersection layout for each intersection using the possible intersection layouts for each intersection; and,
b) generating a candidate wall layout for each wall in accordance with the candidate intersection layouts.

11) A method according to claim 9 or claim 10, wherein the method includes, in the one or more processing devices, generating a modified block layout by:
a) determining a selected intersection in the candidate block layout; and,
b) at least one of:
i) updating a candidate intersection layout of the selected intersection by selecting a next one of the number of possible intersection layouts; and,
ii) if each possible intersection layout has been used for the selected intersection, determining a different selected intersection.

12) A method according to any one of the claims 9 to 11, wherein the method includes, in the one or more processing devices, updating the candidate block layout if the modified block layout at least one of:
a) is better than the candidate block layout; and,
b) has a lower cost than the candidate block layout.

13) A method according to any one of the claims 9 to 12, wherein the criteria includes at least one of:
a) a defined total number of iterations have been performed; and,
b) the candidate block layout has not been updated for a defined number of iterations.

14) A method according to any one of the claims 1 to 13, wherein the method includes, in the one or more processing devices, determining possible intersection layouts for an intersection by:
a) determining an intersection type; and,
b) retrieving a list of possible intersection layouts associated with the intersection type.

15) A method according to any one of the claims 1 to 14, wherein the method includes, in the one or more processing devices, determining possible intersection layouts for an intersection by:
a) retrieving layout rules; and,
b) using the layout rules to select possible intersection layouts.

16) A method according to claim 15, wherein the layout rules are dependent on a block layout of an adjacent block course.

17) A method according to any one of the claims 1 to 16, wherein each block layout includes at least one of:
a) a single block course of blocks; and,
b) two block courses of blocks.

18) A method according to any one of the claims 1 to 17, wherein the block layouts can include blocks having different block types.

19) A method according to claim 18, wherein the different block types include at least one of:
a) blocks for internal walls;
b) blocks for external walls;
c) full blocks;
d) quarter blocks;
e) half blocks; and,
f) three quarter blocks.

20) A method according to any one of the claims 1 to 19, wherein the method includes, in the one or more processing devices, generating a block layout for each of a plurality of block courses.

21) A method according to any one of the claims 1 to 20, wherein the plan data is indicative of wall segments defining at least wall lengths and wall end points.

22) A method according to any one of the claims 1 to 21, wherein the method includes, in the one or more processing devices, acquiring plan data at least one of:
a) using user input commands;
b) from a computer aided design package; and,
c) from a data store.

23) A method according to any one of the claims 1 to 22, wherein a grid is used in designing the block layouts.

24) A method according to claim 23, wherein the grid comprises square grid elements.

25) A method according to claim 24, wherein dimensions of the grid elements are indicative of a minimum block dimension.

26) A method according to claim 25, wherein the minimum block dimension is a block width.

27) A method according to any one of claims 23 to 26, wherein wall segments are extracted from the plan data and overlayed onto the grid so that each wall segment is indicative of a number of grid elements.

28) A method according to claim 27, wherein the different block layouts are generated by fitting different combinations of blocks onto the grid elements associated with each wall segment.

29) A method according to any one of the claims 1 to 28, wherein the method includes, in the one or more processing devices, generating layout data using selected block layout(s).

30) A method according to any one of the claims 1 to 29, wherein the method includes, in the one or more processing devices:
a) acquiring block layout data indicative of block layouts for a number of block courses;
b) identifying one or more sequence rules;
c) generating different block sequences, each block sequence specifying an order in which blocks should be placed and being generated at least in part based on the sequence rules; and,
d) selecting one of the different block sequences.

31) A method according to claim 30, wherein the method includes, in the one or more processing devices, generating block sequence data using the selected block sequence.

32) A method according to any one of the claims 1 to 31, wherein the block layout is indicative of position coordinates for each block.

33) A method for controlling a block laying machine to construct a building, the block laying machine including a block laying head comprising a robot arm and end effector for placing blocks, the block laying head mounted at the end of a boom for positioning the head, the method including in a control system:
a) receiving block layout data generated according to the method of claim 29; and,
b) controlling at least one of the boom and robot arm so as to allow the end effector to position blocks according to the block layout data.

34) A method according to claim 32, wherein the method includes, in the control system:
a) receiving block sequence data generated according to the method of claim 31; and,
b) controlling at least one of the boom and robot arm so as to allow the end effector to position blocks according to the block sequence data.

35) A method according to claim 33, wherein the block sequence data results in the block laying machine constructing the building by laying blocks of at least some courses simultaneously.

36) A system for designing block layouts for use in block placement during construction, the system including, one or more electronic processing devices configured to:
a) acquire plan data indicative of a construction plan;
b) identify walls and intersections within the construction plan;
c) identify a number of possible intersection layouts for each intersection;
d) generate different block layouts, each block layout including:
i) a combination of intersection layouts, the combination including one of the number of possible intersection layouts for each intersection; and,
ii) at least one wall layout for each wall, the wall layouts being generated based on the combination of intersection layouts; and,
e) select one of the different block layouts.

37) A computer program product for designing block layouts for use in block placement during construction, the computer program product including computer executable code which when executed using one or more suitably programmed electronic processing devices causes the one or more processing devices to:
a) acquire plan data indicative of a construction plan;
b) identify walls and intersections within the construction plan;
c) identify a number of possible intersection layouts for each intersection;
d) generate different block layouts, each block layout including:
i) a combination of intersection layouts, the combination including one of the number of possible intersection layouts for each intersection; and,
ii) at least one wall layout for each wall, the wall layouts being generated based on the combination of intersection layouts; and,
e) select one of the different block layouts.
